(19) United States
(12) Patent Application Publication
(10) Pub. No.: US 2026/0371800 A1
(43) Pub. Date: Nov. 19, 2026

(54) SEMICONDUCTOR PACKAGE STRUCTURE

(71) Applicant: Advanced Semiconductor Engineering, Inc., Kaohsiung (TW)

(72) Inventors: Hsun-Wei CHAN, Taoyuan (TW); Shih-Chieh TANG, Taipei (TW); Hsin-Ying HO, Taoyuan (TW)

(73) Assignee: Advanced Semiconductor Engineering, Inc., Kaohsiung (TW)

(21) Appl. No.: 19/208,525

(22) Filed: May 14, 2025

(51) Int. Cl. H10H 20/856

(52) U.S. Cl. CPC H10H 20/856

(57) ABSTRACT

A semiconductor package structure is provided. The semiconductor package structure includes an optical component, a first reflective element, and a second reflective element. The optical component has an emitting surface. The first reflective element encapsulates the optical component. The second reflective element is over the emitting surface and contacts the first reflective element. A first portion of the emitting surface is exposed by the second reflective element.

### BACKGROUND

### 1. Technical Field

The present disclosure relates generally to a semiconductor package structure.

### 2. Description of the Related Art

Optical devices have become progressively more complex, driven at least in part by the demand for smaller sizes and enhanced light-emitting efficiency. Performance of an optical device package may be adversely affected by miniaturization due to the reduction of the light-emitting area. Accordingly, it would be desirable to provide an optical device package with a satisfactory light-emitting efficiency and uniformity.

### SUMMARY

In one or more arrangements, a semiconductor package structure includes an optical component, a first reflective element, and a second reflective element. The optical component has an emitting surface. The first reflective element encapsulates the optical component. The second reflective element is over the emitting surface and contacts the first reflective element. A first portion of the emitting surface is exposed by the second reflective element.

In one or more arrangements, a semiconductor package structure includes an optical component and a first reflective element. The optical component has an emitting surface. The emitting surface includes a first region and a second region. A light emitting uniformity of the second region is lower than a light emitting uniformity of the first region. The first reflective element covers the second region of the emitting surface and exposes the first region of the emitting surface.

In one or more arrangements, a semiconductor package structure includes an optical component and a reflective element. The optical component has an emitting surface configured to emit a light of a varying intensity. The reflective element covers an edge region of the emitting surface and exposes a central region of the emitting surface.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a semiconductor package structure in accordance with some arrangements of the present disclosure.

FIG. 1B is a top view of a semiconductor package structure in accordance with some arrangements of the present disclosure.

FIG. 1C is a top view of a semiconductor package structure in accordance with some arrangements of the present disclosure.

FIG. 1D is a cross-section of a semiconductor package structure in accordance with some arrangements of the present disclosure.

FIG. 2A is a cross-section of a semiconductor package structure in accordance with some arrangements of the present disclosure.

FIG. 2B is a cross-section of a semiconductor package structure in accordance with some arrangements of the present disclosure.

FIG. 2C is a cross-section of a semiconductor package structure in accordance with some arrangements of the present disclosure.

FIG. 2D is a cross-section of a semiconductor package structure in accordance with some arrangements of the present disclosure.

FIG. 2E is a top view of a semiconductor package structure in accordance with some arrangements of the present disclosure.

FIG. 3A is a cross-section of a semiconductor package structure in accordance with some arrangements of the present disclosure.

FIG. 3B is a cross-section of a semiconductor package structure in accordance with some arrangements of the present disclosure.

FIG. 3C is a cross-section of a semiconductor package structure in accordance with some arrangements of the present disclosure.

FIG. 3D is a cross-section of a semiconductor package structure in accordance with some arrangements of the present disclosure.

FIG. 4A is a cross-section of a semiconductor package structure in accordance with some arrangements of the present disclosure.

FIG. 4B is a top view of a semiconductor package structure in accordance with some arrangements of the present disclosure.

FIG. 4C is a cross-section of a semiconductor package structure in accordance with some arrangements of the present disclosure.

FIG. 5A is a cross-section of a semiconductor package structure in accordance with some arrangements of the present disclosure.

FIG. 5B is a cross-section of a semiconductor package structure in accordance with some arrangements of the present disclosure.

FIG. 5C is a cross-section of a semiconductor package structure in accordance with some arrangements of the present disclosure.

FIG. 6A to FIG. 6L illustrate various stages of an exemplary method for forming a semiconductor package structure in accordance with some arrangements of the present disclosure.

FIG. 7A to FIG. 7E illustrate various stages of an exemplary method for forming a semiconductor package structure in accordance with some arrangements of the present disclosure.

FIG. 8A to FIG. 8D illustrate various stages of an exemplary method for forming a semiconductor package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

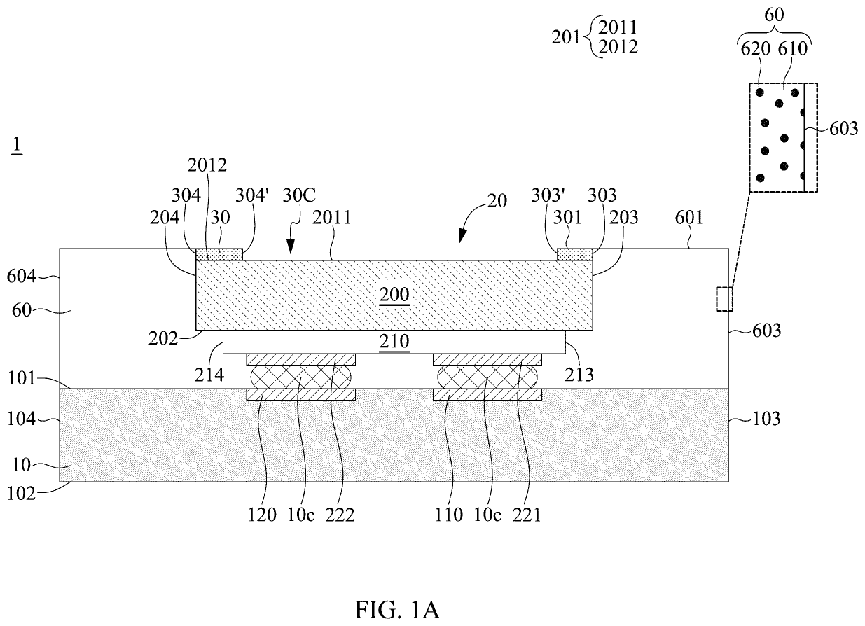

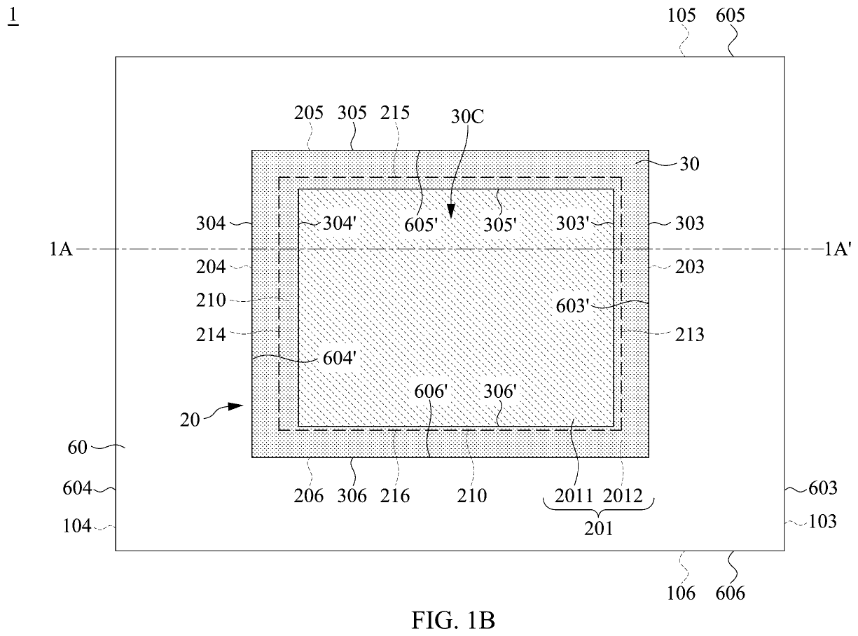

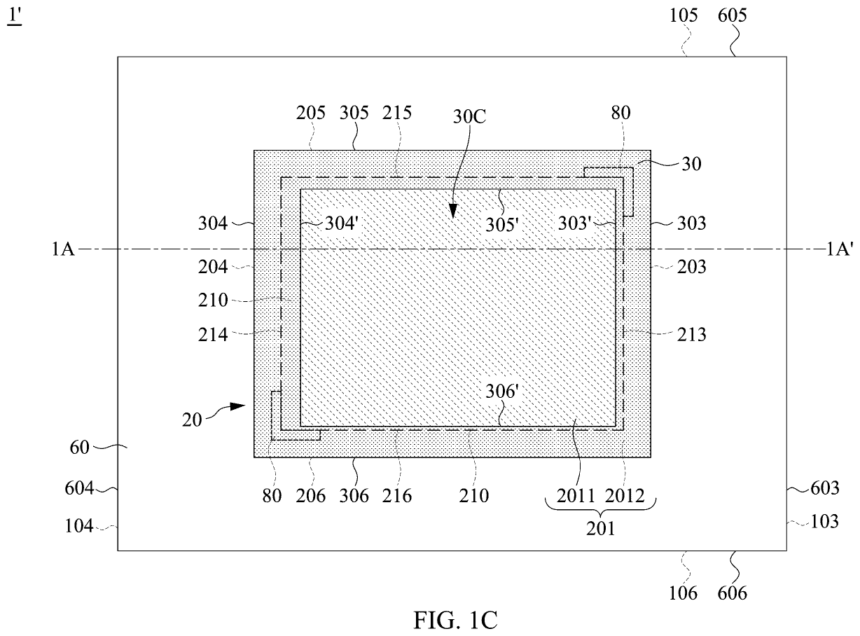

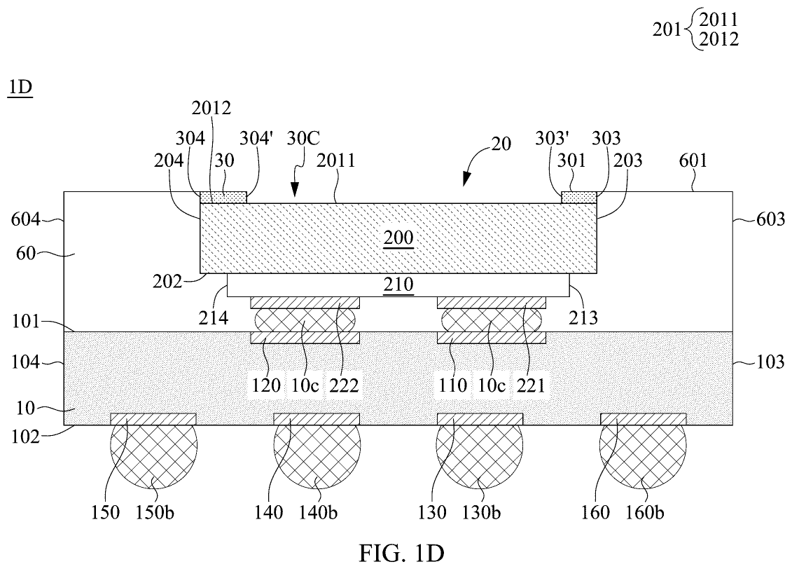

FIG. 1A is a cross-section of a semiconductor package structure 1 in accordance with some arrangements of the present disclosure. FIG. 1B is a top view of a semiconductor package structure 1 in accordance with some arrangements of the present disclosure. In some arrangements, FIG. 1A is a cross-section along a line 1A-1A′ in FIG. 1B. Please be noted that some elements are omitted in FIG. 1B for clarity. The semiconductor package structure 1 may include a substrate 10, an optical component 20, reflective elements 30 and 60, and electrical contacts 10c.

The substrate 10 may include, for example, a printed circuit board (PCB), such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias (also referred to as “through-vias”). The substrate 10 may include a through-via-dense region in which the density of the conductive vias is relatively high and a through-via-sparse or through-via-free region in which the density of the conductive vias is relatively low or there is no conductive via. The substrate 10 may include an integrated fan-out wafer or integrated circuit dies, which may be arranged in an array. In some arrangements, the substrate 10 includes a ceramic material, a metal plate, an organic substrate, a leadframe, or an interposer. In some arrangements, the substrate 10 may include a two-layer substrate which includes a core layer and a conductive material and/or structure disposed on an upper surface and a bottom surface of the substrate 10. The conductive material and/or structure may include a plurality of conductive traces.

In some arrangements, the substrate 10 includes a surface 101 (also referred to as “a top surface,” “an upper surface,” or “a bearing surface”), a surface 102 (also referred to as “a bottom surface” or “a lower surface”), and at least sidewalls 103 and 104. In some arrangements, the substrate 10 supports the optical component 20 and the reflective elements 30 and 60. In some arrangements, the substrate 10 includes pads 110 and 120 exposed from the surface 101. The pads 110 and 120 may be electrically conductive pads. The substrate 10 may be or include a device having an active area (e.g., the surface 101). The semiconductor package structure 1 may further include a guard ring interposed between the active area and an edge of the substrate 10.

The optical component 20 may be disposed over and electrically connected to the substrate 10. The optical component 20 may be flip-chip bonded to the substrate 10. In some arrangements, the optical component 20 is or includes a light emitting component, e.g., a LED. The optical component 20 may be or include a bare semiconductor die. The optical component 20 may be referred to as a light emitting component, a light source, or the like.

In some arrangements, the optical component 20 includes a base layer 200, an emitting layer 210, and electrodes 221 and 222. The emitting layer 210 may be configured to emit a light of a predetermined wavelength range, and the base layer 200 may be or include a semiconductor substrate that is configured to allow the light emitted by the emitting layer 210 to pass through. The light emitted by the emitting layer 210 may have a wavelength from about 400 nm to about 700 nm. The optical component 20 (or the base layer 200) may have a surface 201, a surface 202 opposite to the surface 201, and at least sidewalls 203 and 204. The emitting layer 210 may have at least sidewalls 213 and 214 recessed with respect to at least the sidewalls 203 and 204 of the base layer 200. The surface 201 may be an emitting surface, and the emitting layer 210 may be disposed or formed on the surface 202. In some arrangements, the electrodes 221 and 222 are electrically connected to the pads 110 and 120, respectively. The electrical contacts 10c may connect the optical component 20 (e.g., the electrodes 221 and 222) to the substrate 10 (e.g., the pads 110 and 120). The electrodes 221 and 222 may be metal posts having rounded top surfaces that substantially conform to the substantially spherical profiles of the electrical contacts 10c, such that a relatively large contact areas can be formed, and thus the electrical connection between the electrodes 221 and 222 and the electrical contacts 10c can be enhanced. The electrical contacts 10c may include controlled collapse chip connection (C4) bumps, a ball grid array (BGA), or a land grid array (LGA). In some arrangements, the electrical contacts 10c includes a conductive material having a first acid hardness/softness index, and the pads 110 and 120 include a conductive material having a second acid hardness/softness index different from the first acid hardness/softness index. The electrodes 221 and 222, the electrical contacts 10c, and the pads 110 and 120 collectively may be referred to as a joint structure. The joint structure may include a ruthenium (Ru)-containing region (e.g., the electrodes 221 and 222 and the pads 110 and 120) and a tin (Sn)-containing region (e.g., the electrical contacts 10c).

The surface 201 (or the emitting surface) may include a region 2011 (also referred to as “a first portion” or “a central region”) and a region 2012 (also referred to as “a second portion” or “an edge region”) distinct from the region 2012. In some arrangements, the surface 201 (or the emitting surface) is configured to emit a light of a varying intensity. In some arrangements, a light emitting uniformity of the region 2012 is lower than a light emitting uniformity of the region 2011. In some arrangements, the emitting layer 210 is vertically overlapped with the region 2011 of the surface 201. The optical component 20 may further include an inorganic anti-reflective layer over the region 2011 of the surface 201.

The reflective element 30 may be disposed over the surface 201 of the optical component 20. In some arrangements, the reflective element 30 contacts the reflective element 60. In some arrangements, the region 2011 of the surface 201 (or the emitting surface) is exposed by the reflective element 30. In some arrangements, the reflective element 30 covers the region 2012 and exposes the region 2011 of the surface 201. In some arrangements, the reflective element 30 has a reflectance of equal to or greater than about 95%, 96%, 97%, 98%, or 99% to the light emitted by the optical component 20. In some arrangements, the reflective element 30 is configured to reflect a light that is emitted by the emitting layer 210 and reaching the region 2012 of the surface 201 and to allow the reflected light to emit through the region 2011 of the surface 201. In some arrangements, the reflective element 30 is configured to allow a light having a wavelength from about 900 nm to about 1700 nm to pass through.

In some arrangements, the reflective element 30 includes an oxide material. The reflective element 30 may include a metal oxide. The reflective element 30 may include silicon oxide. The reflective element 30 may be free of a gel layer. In some arrangements, a thickness of the reflective element 30 may be less than about 10 μm, about 8 μm, or about 6 μm. In some arrangements, a thickness of the reflective element 30 may range from about 3 μm to about 5 μm.

In some arrangements, the reflective element 30 includes a distributed Bragg reflector (DBR) element. The reflective element 30 may include a plurality of first material layers and a plurality of second material layers alternately stacked and having different refractive indexes. The number of the material layers of the reflective element 30 may range from about 20 to about 80. A difference in the refractive indexes between the first material layer and the second material layer may range from about 0.4 to about 1, from about 0.6 to about 0.8, or about 0.76. The first material layer and the second material layer may independently include a dielectric layer. The first material layer may be or include SiO₂, and the second material layer may be or include TiO₂. Each of the material layers may have a thickness ranging from several nanometers to dozens of nanometers.

In some arrangements, the reflective element 30 includes an air-penetration layer that exposes the region 2011 of the surface 201 to air. In some arrangements, the reflective element 30 includes an opening 30C exposing the region 2011 of the surface 201. The opening 30C may allow the region 2011 of the surface 201 to expose to air. In some arrangements, the reflective element 30 defines a transparent window (e.g., the opening 30C) overlapped by the region 2011 of the surface 201 (or the emitting surface). In some arrangements, a portion of the base layer 200 forms an optical route to transmit the light emitted from the emitting layer 210 to the opening 30C. The reflective element 30 may have a surface 301 (also referred to as “an upper surface”) and at least sidewalls 303, 304, 303′, and 304′. At least the sidewalls 303′ and 304′ define the opening 30C. In some arrangements, at least the sidewalls 303 and 304 of the reflective element 30 substantially align with at least the sidewalls 203 and 204 of the base layer 200 of the optical component 20, respectively.

The reflective element 60 may be disposed over the substrate 10. In some arrangements, the reflective element 60 encapsulates the optical component 20. In some arrangements, the reflective element 60 covers at least the sidewalls 203 and 204 of the optical component 20. In some arrangements, the reflective element 60 covers the electrical contacts 10c. The reflective element 60 may be referred to as a reflective wall.

In some arrangements, the reflective element 60 includes a surface 601 (also referred to as “an upper surface”) and at least sidewalls 603 and 604. In some arrangements, at least the sidewalls 603 and 604 of the reflective element 60 substantially align with at least the sidewalls 103 and 104 of the substrate 10, respectively. In some arrangements, an elevation of the surface 601 (or the upper surface) of the reflective element 60 is substantially the same as an elevation of the surface 301 (or the upper surface) of the reflective element 30. In some arrangements, the reflective element 60 includes a diffusor material. In some arrangements, the reflective element 60 includes a medium layer 610 and diffusor filler particles 620 dispersed in the medium layer 610. The diffusor filler particles 620 include spherical particles embedded in the medium layer 610 and partial filler particles exposed by the sidewall 603.

In some arrangements, the semiconductor package structure 1 is free of an underfill. In some arrangements, the semiconductor package structure 1 is free of an underfill which may include a light-absorbing material (e.g., an epoxy-based material). According to some arrangements of the present disclosure, with the above design, the diffusor material of the reflective element 60 is advantageous to reflecting the light emitting from the emitting layer 210 and redirecting the light toward the emitting surface without an underfill that may absorb the light, and thus the light emitting efficiency can be increased.

Referring to FIG. 1B, the substrate 10 may have sidewalls 103, 104, 105, and 106. The optical component 20 (or the base layer 210) may have sidewalls 203, 204, 205, and 206. The emitting layer 210 may have sidewalls 213, 214, 215, and 216. The reflective element 30 may have sidewalls 303, 304, 305, and 306. The opening 30C may be defined by sidewalls 303′, 304′, 305′, and 306′ of the reflective element 30. The reflective element 60 may have sidewalls 603, 604, 605, and 606. The reflective element 60 may further have sidewalls 603′, 604′, 605′, and 606′ that contact the sidewalls 203, 204, 205, and 206 of the optical component 20. There may be a misalignment between the reflective element 30 and the region 2011 of the surface 201. In some arrangements, a center of the emitting layer 210 is misaligned with a center of the region 2011 of the surface 201 (or a center of the opening 30C). In some arrangements, a center of the reflective element 30 is misaligned with a center of the region 2011 of the surface 201 (or a center of the opening 30C). In some arrangements, the region 2012 of the surface 201 is covered by the reflective element 30, and the region 2011 is surrounded by the region 2012 (or the reflective element 30) from a top view perspective.

FIG. 1C is a top view of a semiconductor package structure 1′ in accordance with some arrangements of the present disclosure. In some arrangements, FIG. 1A shows a cross-section along a line 1A-1A′ in FIG. 1C.

In some arrangements, the semiconductor package structure 1′ further includes alignment marks 80. The alignment marks 80 may include a first alignment mark and a second alignment mark disposed at opposite corners of the optical component 20. The alignment marks 80 may be disposed at adjacent corners of the optical component 20. The alignment marks 80 can be observed by a detector utilizing a light having a wavelength ranging from about 900 nm to about 1700 nm to determine a periphery of the region 2012 of the surface 201 for forming the reflective element 30 on the optical component 20. The alignment marks 80 may include probe marks, e.g., adjacent probe marks at adjacent corners of the optical component 20.

FIG. 1D is a cross-section of a semiconductor package structure 1D in accordance with some arrangements of the present disclosure. The semiconductor package structure 1D is similar to the semiconductor package structure 1 in FIG. 1A, and the differences therebetween are described as follows. In some arrangements, FIG. 1D shows a cross-section along a line 1A-1A′ in FIG. 1B and/or in FIG. 1C.

In some arrangements, the substrate 10 further includes pads 130, 140, 150, and 160 exposed from the surface 102. The pads 130, 140, 150, and 160 may be electrically conductive pads. In some arrangements, referring to FIG. 1B and FIG. 1D, the pads 110 and 120 are elongated metal pads that have rectangular shapes extending substantially in parallel to the sidewalls 203 and 204 from a top view perspective. In some arrangements, the pads 130, 140, 150, and 160 are non-elongated metal pads.

In some arrangements, the semiconductor package structure 1D further includes bumps 130a, 140a, 150a, and 160a that connect to the pads 130, 140, 150, and 160, respectively. All elongated metal pads (the pads 110 and 120) may be electrically connected to the electrodes of the optical component 20. All neighboring bumps 130b, 140b, 150b, and 160b are disposed on the surface 102 of the substrate 100. Referring to FIG. 1B, a plurality of bumps 150b may be arranged in a column along the sidewalls 203 and 204 from a top view perspective, and a plurality of bumps 160b may be arranged in a column along the sidewalls 203 and 204 from a top view perspective. The bumps 130b and 140b may be electrically connected to the electrodes 221 and 222 through the pads 130 and 140. All the other neighboring bumps (e.g., the bumps 150b and 160b) may serve as ground bumps or RF signal bumps. The semiconductor package structure 1D may further include a carrier (not shown in drawings), the device (e.g., the substrate 10) may be disposed over and electrically connected to the carrier through the bumps 130b, 140b, 150b, and 160b.

The front surface (e.g., the surface 201) of the optical component 20 may emit a light having a varying intensity, and the light may have a relatively poor light emitting uniformity at edges of the front surface. As a result, despite that the light may have a relatively high light emitting uniformity at the central region of the front surface, the light emitting uniformity of the entire front surface is adversely affected since it is difficult to increase the light emitting uniformity of the entire front surface simply by adjusting intensity and intensity distribution of the emitted light. To solve the above issue, the edges of the front surface may be covered by a gel layer, and only the central region with a relatively high light emitting uniformity is allowed to emit the light. However, the gel layer requires to have a relatively large thickness (e.g., 10 μm or greater) so as to possess a sufficient coverage and reflectance for the light at the edges of the front surface, which undesirably increases the thickness of the semiconductor package structure. In addition, a plurality of optical components 20 are picked and placed on a carrier for a plurality of gel layers to be dispensed, and then each of the gel layers is dispensed on each of the corresponding optical component 20 instead of forming the gel layers by printing a gel material on a wafer-level or a strip-level optical component structure using a mask defining a plurality of openings that correspond to the optical components 20. Since distances between the optical components 20 may vary, and actual positions of the optical components 20 may be shifted from predetermined positions due to processing tolerances of the pick-and-place operation, such that accurate alignments of the gel layers to the corresponding optical components 20 may be difficult to achieve. Therefore, with the relatively large shift tolerance, it is difficult to control and/or adjust the size of the effective emitting area, and thus the actual emitting area is reduced because the coverage area is increased to make sure that the edges are entirely covered.

To solve the above issue raised by the gel layers, a metal plating may be used to cover the edges of the front surface of the optical component 20. However, the metal plating is exposed to air and can be easily oxidized, corroded, and degraded, which can seriously lower the quality and the reliability of the semiconductor package structure. If an additional encapsulating film is used to cover the front surface of the optical component 20 to protect the metal plating from exposure to air, since total reflection may occur when the light passes through the encapsulating film, the encapsulating film that may cover the emitting surface can decrease the light emitting intensity as well as the light emitting uniformity.

According to some arrangements of the present disclosure, the reflective element 30 covers the region 2012 (also referred to as “a dark region” or “an edge region”) having a relatively poor light emitting uniformity and exposes the region 2011 (also referred to as “a bright region” or “a central region”) having a relatively high light emitting uniformity. Therefore, the light emitting uniformity of the emitting surface (e.g., the surface 201) of the optical component 20 can be increased significantly, lights can be reflected by the reflective element 30 and redirected to be emitted from the region 2011 of the surface 201 through internal reflection of lights, and thus loss in light emitting efficiency can be decreased.

In addition, according to some arrangements of the present disclosure, the reflective element 30 includes an oxide material and has a thickness of less than about 10 μm. Therefore, the reflective element 30 can be less vulnerable to oxidation, corrosion, and degradation and have a relatively small thickness while still providing a satisfactory reflectance for the light emitted by the emitting layer 210 and thereby reducing loss in light emitting efficiency. Accordingly, the stability and the reliability of the semiconductor package structure can be increased.

Moreover, according to some arrangements of the present disclosure, the reflective element 30 is configured to reflect the light emitted from the emitting layer 210 and allow a light having a wavelength from about 900 nm to about 1700 nm to pass through. With the above design, the emitting layer 210 and the alignment marks 80 can be observed by a detector utilizing a light having a wavelength ranging from about 900 nm to about 1700 nm to determine a periphery of the region 2012 of the surface 201 for forming the reflective element 30 on the optical component 20. Therefore, the alignment accuracy of the reflective element 30 with the region 2012 and/or the region 2011 of the surface 201 can be increased significantly, and thus the area of the region 2012 can be as small as it requires, such that the area of the region 2011 with the relatively high light emitting uniformity can remain as large as possible. Accordingly, the light emitting efficiency can be increased significantly.

Furthermore, according to some arrangements of the present disclosure, the reflective element 30 is or includes a DBR element. Therefore, the reflectance for the light emitted by the emitting layer 210 is relatively high, the thickness of the reflective element 30 is relatively small, and thus the light emitting efficiency and the uniformity can be increased with the semiconductor package structure having a relatively small thickness, thereby the overall size of the semiconductor package structure is reduced significantly.

In addition, according to some arrangements of the present disclosure, the reflective element 60 allows the lights that emit toward sidewalls of the optical component 20 to be reflected back toward inside of the optical component 20 and then redirected toward the emitting surface (e.g., the region 2011 of the surface 201). Therefore, the light emitting efficiency can be increased significantly, and the loss in light intensity can be reduced.

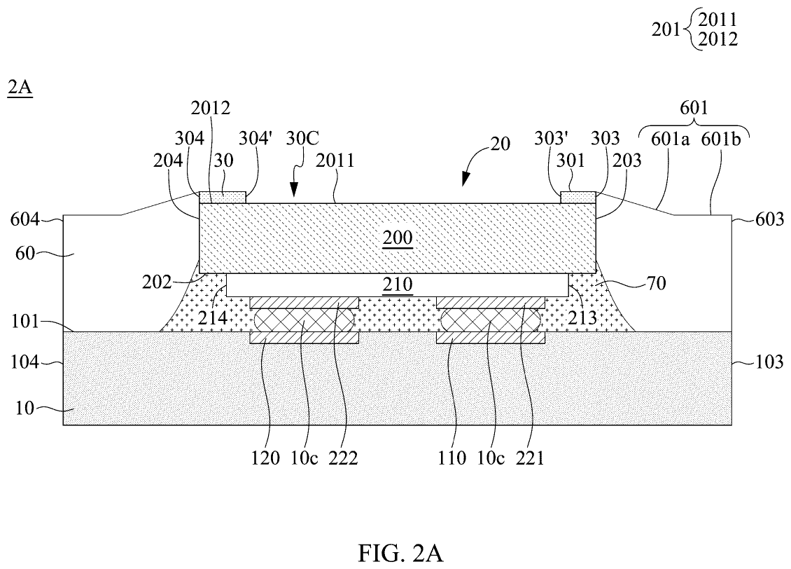

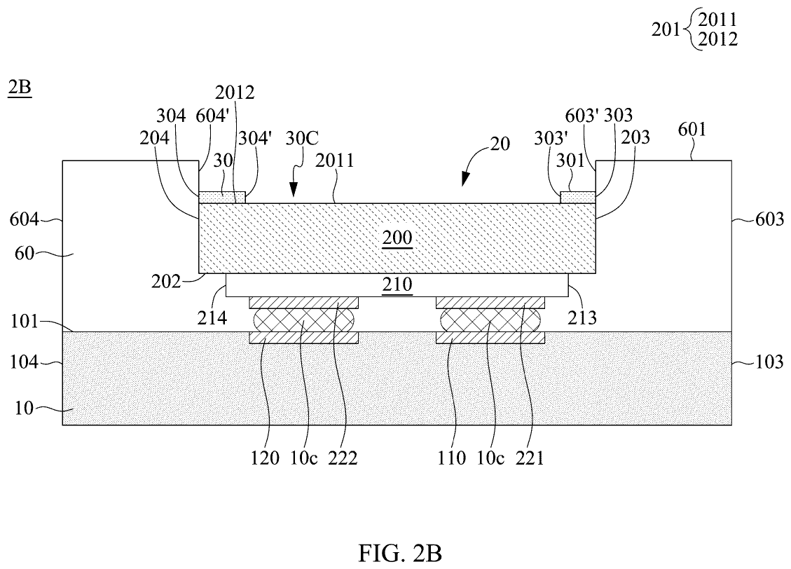

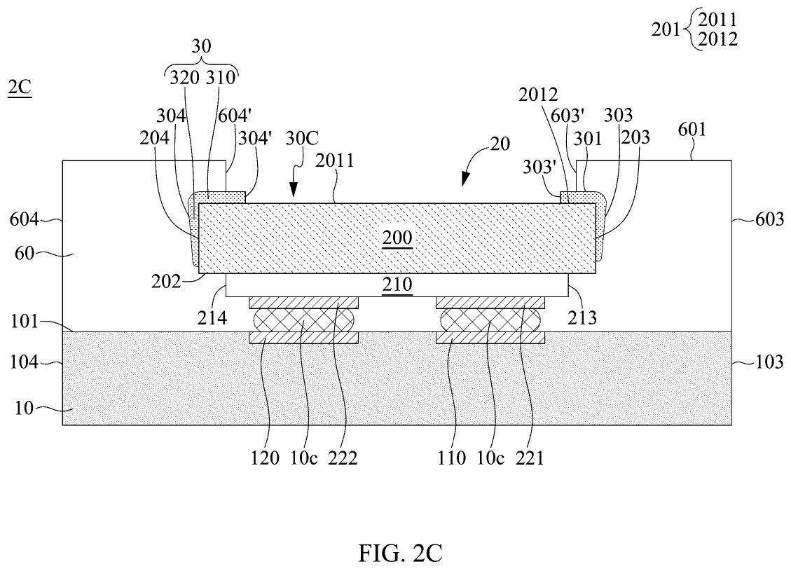

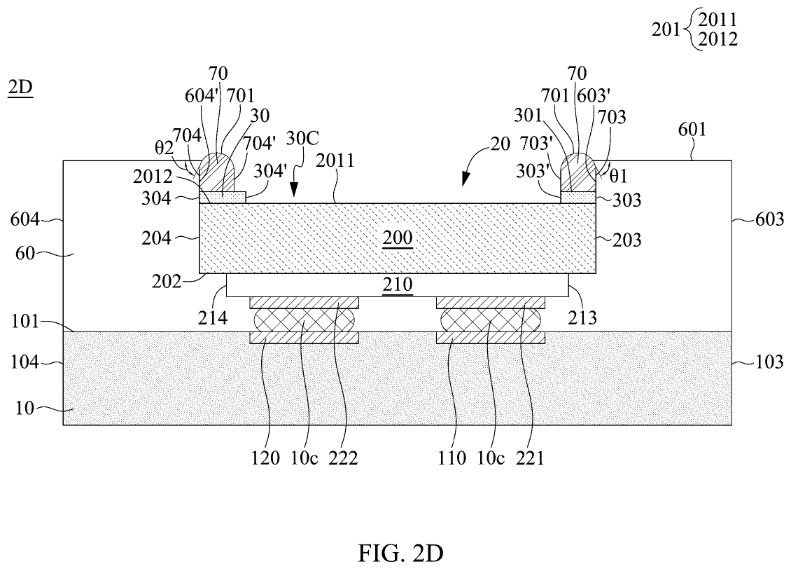

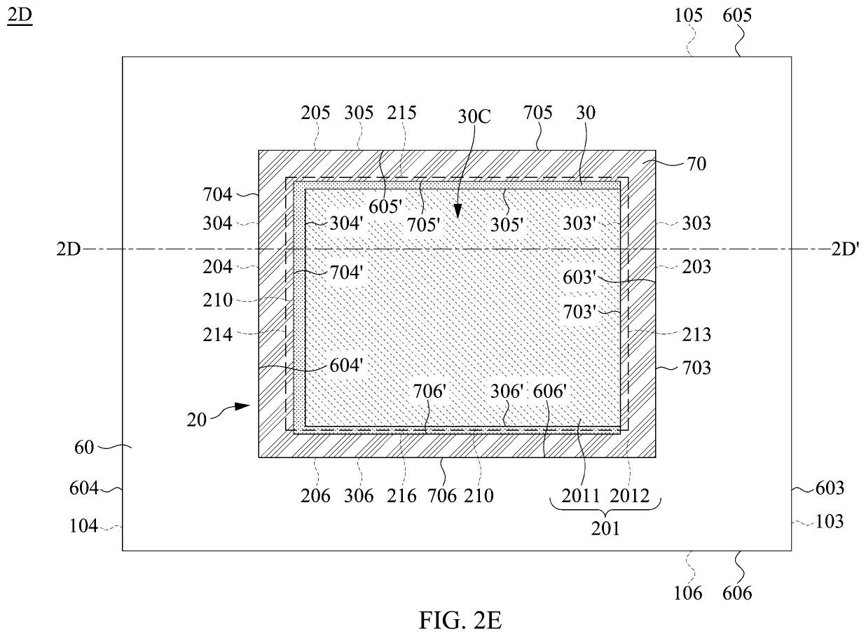

FIG. 2A is a cross-section of a semiconductor package structure 2A in accordance with some arrangements of the present disclosure. The semiconductor package structure 2A is similar to the semiconductor package structure 1 in FIG. 1A, and the differences therebetween are described as follows.

In some arrangements, an elevation of an upper surface (e.g., the surface 601 including surfaces 601a and 601b) of the reflective element 60 is lower than an elevation of an upper surface (e.g., the surface 301) of the reflective element 30 with respect to the emitting surface (e.g., the surface 201) of the optical component 20. In some arrangements, an elevation of an upper surface (e.g., the surfaces 601a and 601b) of the reflective element 60 lowers in a direction away from the optical component 20 with respect to the emitting surface (e.g., the surface 201). In some arrangements, the reflective element 60 extends over a sloping side (e.g., the surface 601a) of the reflective element 60.

In some arrangements, the semiconductor package structure 2A further includes a baffle structure 70 (or a protective element) encapsulating the emitting layer 210, the pads 110 and 120, the electrodes 221 and 222, and the electrical contacts 10c. The baffle structure 70 may be or include an underfill. In some arrangements, the baffle structure 70 (or the underfill) includes a diffusor material. In some arrangements, the baffle structure 70 (or the underfill) is substantially free of a light-absorbing material (e.g., an epoxy-based material). According to some arrangements of the present disclosure, with the above design, the diffusor material of the baffle structure 70 (or the underfill) is advantageous to reflecting the light emitting from the emitting layer 210 and redirecting the light toward the emitting surface, and thus the light emitting efficiency can be increased.

FIG. 2B is a cross-section of a semiconductor package structure 2B in accordance with some arrangements of the present disclosure. The semiconductor package structure 2B is similar to the semiconductor package structure 1 in FIG. 1A, and the differences therebetween are described as follows.

In some arrangements, an elevation of an upper surface (e.g., the surface 601) of the reflective element 60 is higher than an elevation of an upper surface (e.g., the surface 301) of the reflective element 30 with respect to the emitting surface (e.g., the surface 201) of the optical component 20. In some arrangements, the reflective element 60 further includes at least sidewalls 603′ and 604′ facing each other and exposed by the reflective element 30. In some arrangements, the reflective element 60 includes one or more protrusions that protrude beyond the surface 301 of the reflective element 30. In some arrangements, the protrusion of the reflective element 60 is adjacent to the region 2012 of the surface 201 and contacts the reflective element 30. According to some arrangements of the present disclosure, the protrusion may be configured to reduce light leakage at the edges of the surface 201.

FIG. 2C is a cross-section of a semiconductor package structure 2C in accordance with some arrangements of the present disclosure. The semiconductor package structure 2C is similar to the semiconductor package structure 1 in FIG. 1A, and the differences therebetween are described as follows.

In some arrangements, the reflective element 30 includes a portion 310 (also referred to as “a horizontal portion”) over the region 2012 of the surface 201 and a portion 320 (also referred to as “a vertical portion”) extending over the sidewalls of the optical component 20. The portion 320 may taper toward the substrate 10.

In some arrangements, the reflective element 60 (or the protrusion of the reflective element) covers a portion of the surface 301 of the reflective element 30. According to some arrangements of the present disclosure, the protrusion may be configured to reduce light leakage at the edges of the surface 201.

FIG. 2D is a cross-section of a semiconductor package structure 2D in accordance with some arrangements of the present disclosure. FIG. 2E is a top view of a semiconductor package structure 2D in accordance with some arrangements of the present disclosure. In some arrangements, FIG. 2D is a cross-section along a line 2D-2D′ in FIG. 2E. The semiconductor package structure 2D is similar to the semiconductor package structure 1 in FIG. 1A, and the differences therebetween are described as follows. Please be noted that some elements are omitted in FIG. 2E for clarity.

In some arrangements, the semiconductor package structure 2D further includes a baffle structure 70 (also referred to as “a dam structure”) contacting the reflective element 60. In some arrangements, an elevation of an upper surface (e.g., the surface 601) of the reflective element 60 is lower than an elevation of an upper surface (e.g., a surface 701) of the baffle structure 70 with respect to the emitting surface (e.g., the surface 201) of the optical component 20. In some arrangements, the baffle structure 70 includes a ring-shaped dam portion over and contacting the reflective element 30. In some arrangements, the baffle structure 70 includes sidewalls 703′, 704′, 705′, and 706′ exposed by the reflective element 30 and exposed to the opening 30C. According to some arrangements of the present disclosure, the baffle structure 70 can reduce the optical distortion caused by edge effects, thereby improving the overall quality of the image generated by a device including the semiconductor package structure of the present disclosure.

In some arrangements, the baffle structure 70 further includes sidewalls 703, 704, 705, and 706 that contact the sidewalls 603′, 604′, 605′, and 606′ of the reflective element 60. In some arrangements, a profile angle θ1 of the reflective element 60 defined by the sidewall 603′ and the surface 601 is less than 90 degrees. In some arrangements, a profile angle θ2 of the reflective element 60 defined by the sidewall 604′ and the surface 601 is less than 90 degrees. The angles θ1 and θ2 may be the same or different from each other. According to some arrangements of the present disclosure, the baffle structure 70 can block lights from accidentally emitting out of the reflective element 60 from the sidewalls 603′, 604′, 605′, and 606′.

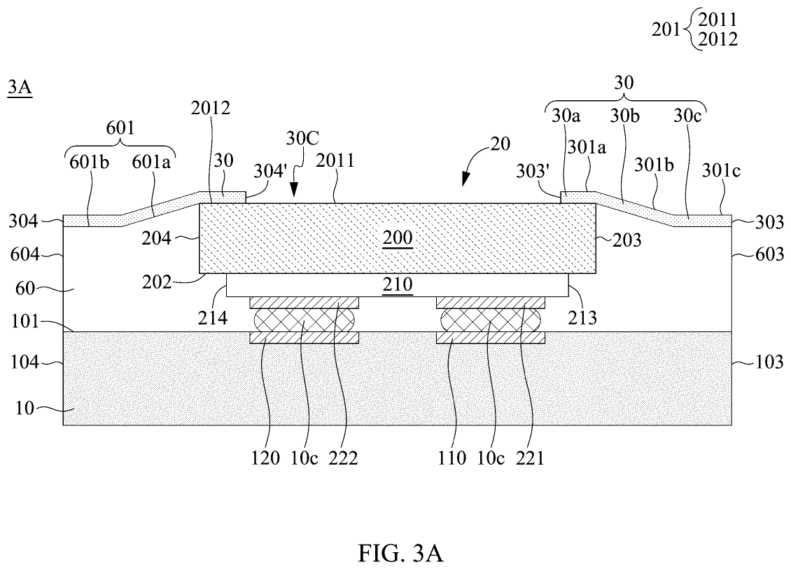

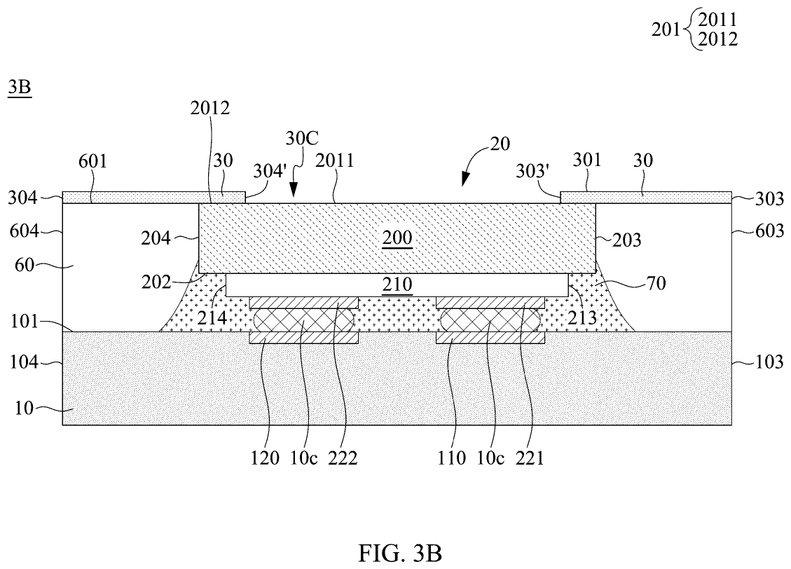

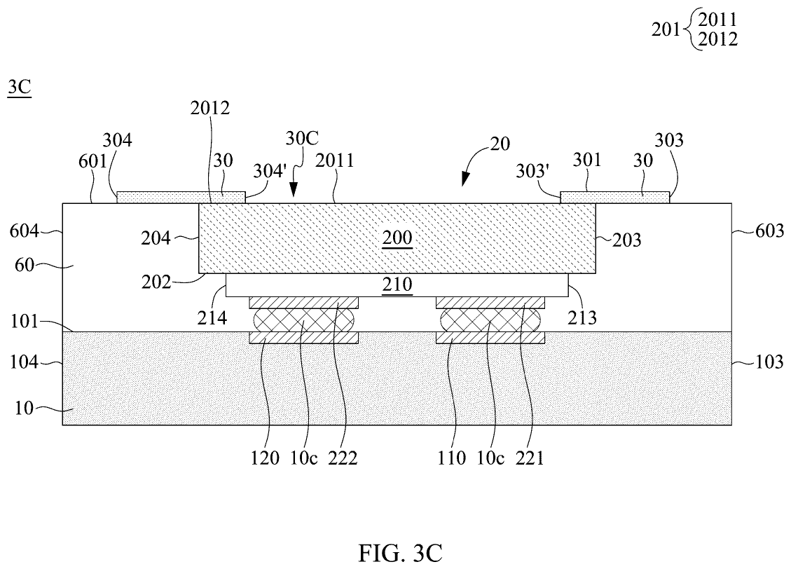

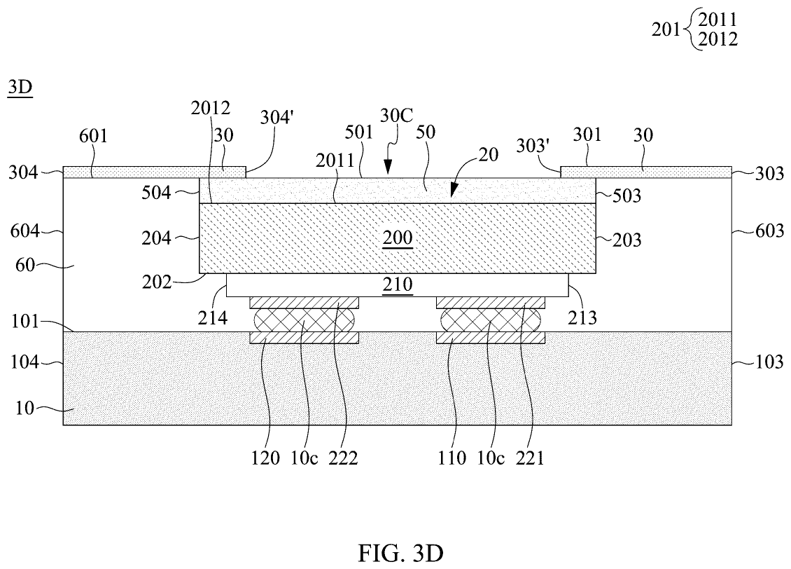

FIG. 3A is a cross-section of a semiconductor package structure 3A in accordance with some arrangements of the present disclosure. The semiconductor package structure 3A is similar to the semiconductor package structure 1 in FIG. 1A, and the differences therebetween are described as follows.

In some arrangements, the reflective element 30 includes an anti-warpage bar protruding from at least a sidewall (e.g., the sidewalls 203 and 204) of the optical component 20 in a cross-sectional view perspective. In some arrangements, an elevation of an upper surface (e.g., the surface 301 including surfaces 301a, 301b, and 301c) of the anti-warpage bar lowers in a direction away from the optical component 20. In some arrangements, the reflective element 30 extends over an upper surface (e.g., the surface 601) of the reflective element 60. According to some arrangements, the reflective element 30 (or the anti-warpage bar) can reduce the warpage of the semiconductor package structure resulting from the mismatch of coefficients of thermal expansion (CTEs) between the reflective element 60 and the base layer 200 and can further block lights from accidentally emitting out of the reflective element 60 from the surface 601.

In some arrangements, the reflective element 30 includes functional tiers 30a, 30b, and 30c at different elevations. In some arrangements, the functional tier 30a (also referred to as “a first functional tier”) has an upper surface (e.g., the surface 301a), the functional tier 30b (also referred to as “a second functional tier”) has an upper slope surface (e.g., the surface 301b), and the functional tier 30c (also referred to as “a third functional tier”) has an upper surface (e.g., the surface 301c) lower than the upper surface of the functional tier 30a. In some arrangements, the functional tier 30a is disposed over the optical component 20 and configured to define the region 2011 of the surface 201, and the functional tiers 30b and 30c are disposed over the reflective element 60 and configured to block light leakage. In some arrangements, the functional tier 30a is configured to reflect lights and prevent the lights from emitting out of the region 2012 of the surface 201, and the functional tiers 30b and 30c are configured to reflect lights and prevent the lights from emitting out of the sidewalls of the optical component 20.

FIG. 3B is a cross-section of a semiconductor package structure 3B in accordance with some arrangements of the present disclosure. The semiconductor package structure 3B is similar to the semiconductor package structure 1 in FIG. 1A, and the differences therebetween are described as follows.

In some arrangements, the reflective element 30 includes an anti-warpage bar protruding from at least a sidewall (e.g., the sidewalls 203 and 204) of the optical component 20 in a cross-sectional view perspective. According to some arrangements, the reflective element 30 (or the anti-warpage bar) can reduce the warpage of the semiconductor package structure resulting from the mismatch of CTEs between the reflective element 60 and the base layer 200 and can further block lights from accidentally emitting out of the reflective element 60 from the surface 601.

FIG. 3C is a cross-section of a semiconductor package structure 3C in accordance with some arrangements of the present disclosure. The semiconductor package structure 3C is similar to the semiconductor package structure 1 in FIG. 1A, and the differences therebetween are described as follows.

In some arrangements, the reflective element 30 includes an anti-warpage bar protruding from at least a sidewall (e.g., the sidewalls 203 and 204) of the optical component 20 in a cross-sectional view perspective. A portion of the surface 601 distal from the emitting surface (e.g., the region 2011 of the surface 201) of the optical component 20 may be exposed by the reflective element 30. According to some arrangements, the reflective element 30 (or the anti-warpage bar) can reduce the warpage of the semiconductor package structure resulting from the mismatch of CTEs between the reflective element 60 and the base layer 200 and can further block lights from accidentally emitting out of the reflective element 60 from the surface 601.

FIG. 3D is a cross-section of a semiconductor package structure 3D in accordance with some arrangements of the present disclosure. The semiconductor package structure 3D is similar to the semiconductor package structure 1 in FIG. 1A, and the differences therebetween are described as follows.

In some arrangements, the transparent cover 50 covers the region 2011 of the surface 201 (or the emitting surface) and contacts the reflective element 30.

In some arrangements, the semiconductor package structure 3D further includes a transparent cover 50 over the region 2011 of the surface 201 (or the emitting surface). In some arrangements, the transparent cover 50 is overlapped by the opening 30C (or the transparent window). In some arrangements, the transparent cover 50 includes a polymer lens layer. The transparent cover 50 in configured to increase the light emitting uniformity of the emitting surface of the optical component 20. According to some arrangements, the reflective element 30 (or the anti-warpage bar) can reduce the warpage of the semiconductor package structure resulting from the mismatch of CTEs between the reflective element 60 and the base layer 200 and can further block lights from accidentally emitting out of the reflective element 60 from the surface 601.

In some arrangements, the transparent cover 50 includes an embedded buffer connecting the reflective element 30 to the surface 201 (or the emitting surface). In some arrangements, a CTE of the reflective element 60 is greater than a CTE of the base layer 200. In some arrangements, a CTE of the transparent cover 50 is greater than the CTE of the base layer 200. In some arrangements, a difference in the CTEs between the reflective element 30 and the transparent cover 50 is between a difference in the CTEs between the reflective element 30 and the base layer 200 and a difference in the CTEs between the reflective element 30 and the reflective element 60. According to some arrangements of the present disclosure, the reflective element 30 (or the anti-warpage bar) contacts the reflective element 60 and the transparent cover 50 instead of contacting the base layer 200. The CTE difference between the reflective element 30 and the reflective element 60 is closer to the CTE difference between the reflective element 30 and the transparent cover 50 than to the CTE difference between the reflective element 30 and the base layer 200, therefore CTE mismatches at the interface between the reflective element 30 and the reflective element 60 and the interface between the reflective element 30 and the transparent cover 50 are relatively close, which can reduce the delamination of the reflective element 30, particularly at the point where the reflective element 30, the reflective element 60, and the transparent cover 50 contact.

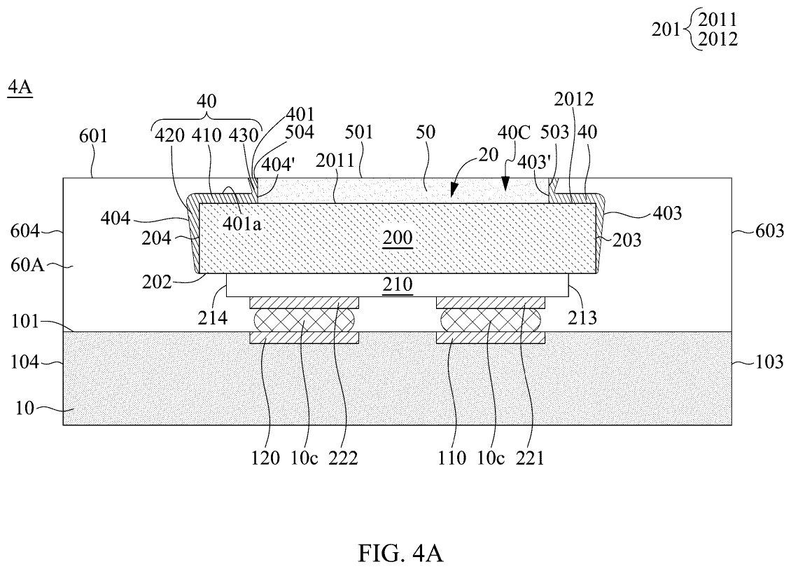

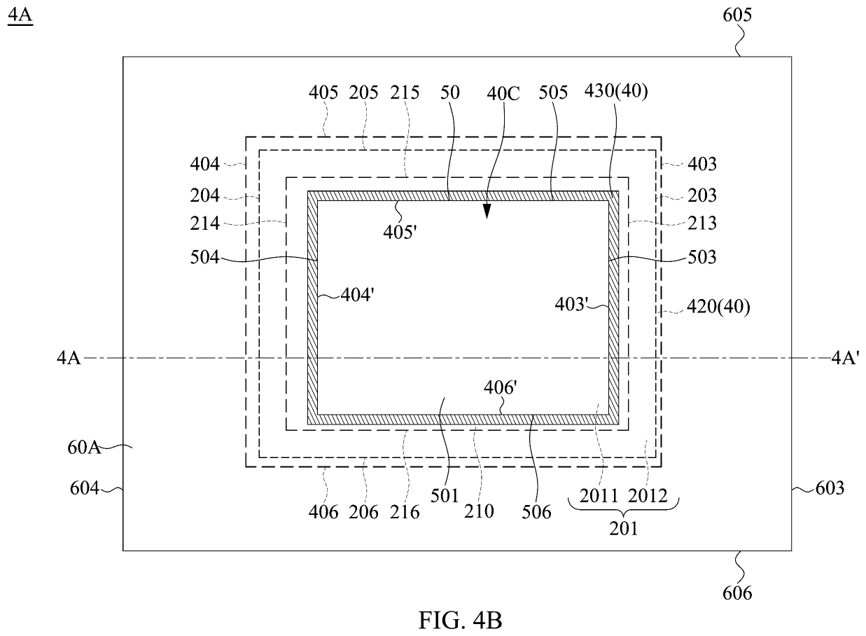

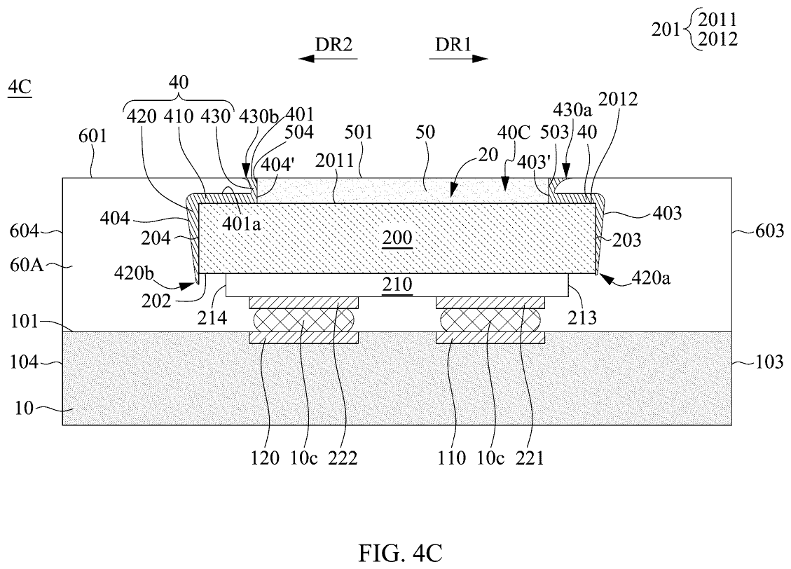

FIG. 4A is a cross-section of a semiconductor package structure 4A in accordance with some arrangements of the present disclosure. FIG. 4B is a top view of a semiconductor package structure 4A in accordance with some arrangements of the present disclosure. In some arrangements, FIG. 4A is a cross-section along a line 4A-4A′ in FIG. 4B. The semiconductor package structure 4A is similar to the semiconductor package structure 1 in FIG. 1A, and the differences therebetween are described as follows. Please be noted that some elements are omitted in FIG. 4B for clarity. The semiconductor package structure 4A may include a substrate 10, an optical component 20, a reflective element 40, a transparent cover 50, a cover element 60A, and electrical contacts 10c.

In some arrangements, the reflective element 40 is disposed over the surface 201 of the optical component 20. In some arrangements, the reflective element 40 is configured to reflect a light that is emitted by the emitting layer 210 and reaching the region 2012 of the surface 201 and to allow the reflected light to emit through the region 2011 of the surface 201. In some arrangements, the reflective element 40 has a reflectance of equal to or greater than about 90%, 91%, 92%, 93%, 94%, or 95% to the light emitted by the optical component 20. The reflective element 40 may be referred to as a mirror coating. In some arrangements, the reflective element 40 includes a metal material or a metal composite material, e.g., aluminum (Al), copper (Cu), gold (Au), or silver (Ag), or an alloy thereof, or other suitable metal or alloy. In some arrangements, the reflective element 40 includes a metal layer. In some arrangements, a thickness of the reflective element 40 may range from about 200 nm to about 500 nm.

The reflective element 40 may have surfaces 401 and 401a (also referred to as “upper surfaces”) and sidewalls 403, 404, 405, 406, 403′, 404′, 405′, and 406′. The sidewalls 403′, 404′, 405′, and 406′ may define the opening 40C. In some arrangements, the reflective element 40 includes portions 410, 420, and 430. The portion 410 may be referred to as a reflective layer, and the portions 420 and 430 may be referred to as reflective walls.

In some arrangements, the reflective element 40 (or the portions 410 and 430) covers the region 2012 (or the edge region) and exposes the region 2011 (or the central region) of the surface 201 (or the emitting surface) of the optical component 20. In some arrangements, the reflective element 40 contacts the cover element 60A. In some arrangements, the reflective element 40 (or the portion 430) includes an opening 40C exposing the region 2011 of the surface 201. In some arrangements, the reflective element 40 (or the portion 430) defines a transparent window (e.g., the opening 40C) overlapped by the region 2011 of the surface 201 (or the emitting surface). In some arrangements, the reflective element 40 (or the portion 420) includes a thermal conductive film extending over at least the sidewalls 203 and 204 of the optical component 20. In some arrangements, a thickness uniformity of portion 420 is less than a thickness uniformity of the portion 410. In some arrangements, the portion 420 (or the reflective wall) tapers in a direction away from the portion 410.

In some arrangements, the transparent cover 50 is overlapped by the transparent window (or the opening 40C). In some arrangements, the transparent cover 50 covers the region 2011 of the surface 201 and contacts the reflective element 40. In some arrangements, an upper surface (e.g., the surface 501) of the transparent cover 50 substantially aligns with an upper surface (e.g., the surface 401) of the reflective element 40.

In some arrangements, the cover element 60A encapsulates the optical component 20. In some arrangements, the cover element 60A encapsulates the reflective element 40. In some arrangements, the cover element 60A contacts the portions 410 and 420 of the reflective element 40. In some arrangements, the cover element 60A covers the sidewalls 203, 204, 205, and 206 of the optical component 20. In some arrangements, the cover element 60A is free from contacting the surface 201. In some arrangements, the cover element 60A includes an encapsulant. In some arrangements, the cover element 60A includes a thermal insulation layer. In some arrangements, the cover element 60A includes a material (e.g., a diffusor material) the same as or similar to that of the reflective element 60 described above.

Referring to FIG. 4B, there may be a misalignment between the reflective element 40 and the region 2011 of the surface 201. In some arrangements, a center of the emitting layer 210 is misaligned with a center of the region 2011 of the surface 201 (or a center of the opening 40C). In some arrangements, a center of the reflective element 40 is misaligned with a center of the region 2011 of the surface 201 (or a center of the opening 40C). In some arrangements, the region 2012 of the surface 201 is covered by the reflective element 40, and the region 2011 is surrounded by the region 2012 (or the reflective element 40) from a top view perspective.

Referring to FIG. 4B, in some arrangements, the reflective element 40 includes at least two outer conductive patterns distributed at corners of the optical component 20. The outer conductive pattern comprises a profile that is conformal to the corner of the optical component 20 from a top view perspective. The reflective element 40 (or the outer conductive patterns) may include at least a conductive adhesive. In some arrangements, the conductive adhesive covers the corner of the optical component 20. The two outer conductive pattern at adjacent corners are connected to each other. According to some arrangements of the present disclosure, the conformal outer conductive patterns (or the conductive adhesive) can further prevent light leakage at corners of the optical component 20. In some arrangements, the reflective element 40 may include conductive patterns that electrically connected to ground, such that the reflective element 40 may also serve as an electrostatic discharge (ESD) protection module. In some arrangements, the reflective element 40 may include at least two conductive patterns that are spaced apart from each other (not shown in FIG. 4B) and configured as different electrical paths that connect to different elements/components. With the above design, the reflective element 40 can serve as not only a light leakage blocker but also electrical paths.

In some arrangements, referring to FIG. 4A, the cover element 60A may be replaced by the reflective element 60, and the reflective element 40 may be omitted. The region 2011 of the surface 201 may be defined by the transparent cover 50, and the reflective element 60 may reflect lights that emit toward the region 2012 of the surface 201 and the sidewalls of the optical component 20 and redirect the lights to emit through the region 2011 of the surface 201 of the optical component 20. With the above design, the manufacturing process can be simplified.

FIG. 4C is a cross-section of a semiconductor package structure 4C in accordance with some arrangements of the present disclosure. The semiconductor package structure 4C is similar to the semiconductor package structure 4A in FIG. 4A, and the differences therebetween are described as follows.

In some arrangements, the reflective element 40 (or the portion 430) includes a bird-beak 430a pointing in a direction DR1 substantially parallel to the surface 201 and an additional bird-beak 430b pointing in a direction DR2 opposite to the direction DR1.

In some arrangements, the reflective element 40 (or the portion 420) includes protrusions 420a and 420b (or tips) that protrude beyond the surface 202 of the base layer 200. In some arrangements, the protrusions 420a and 420b are protruded by different lengths.

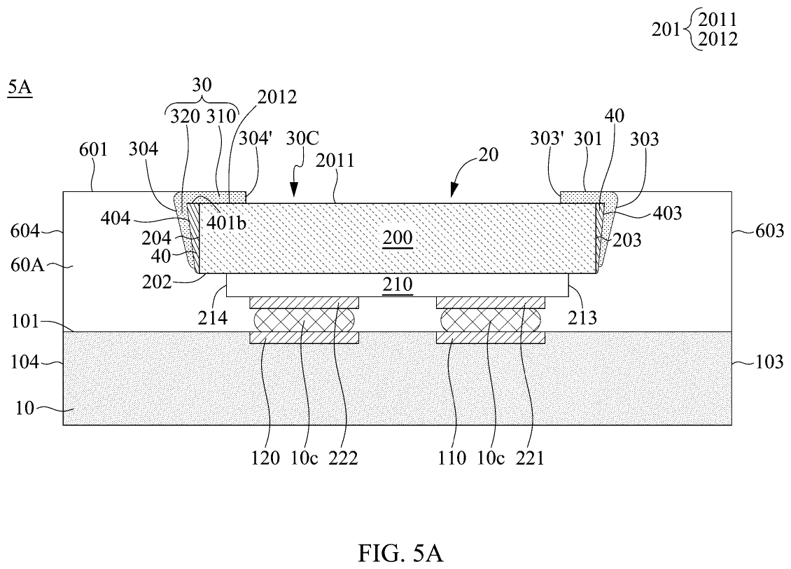

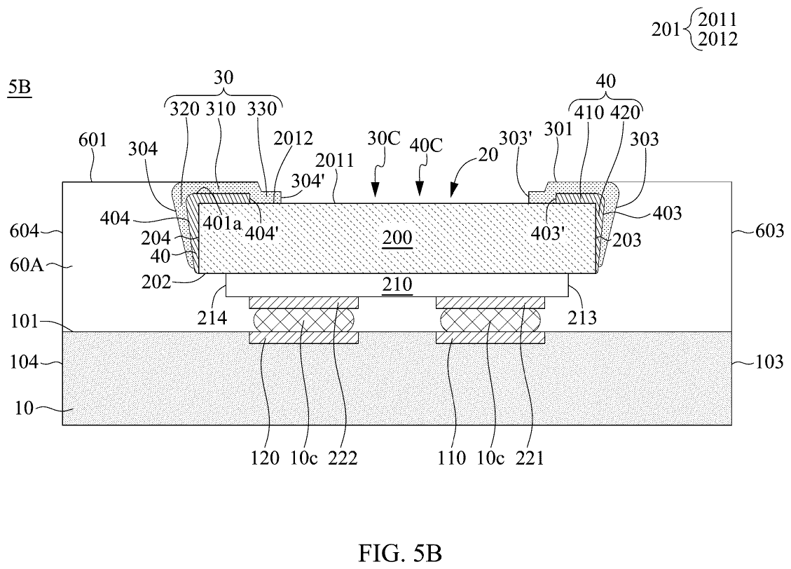

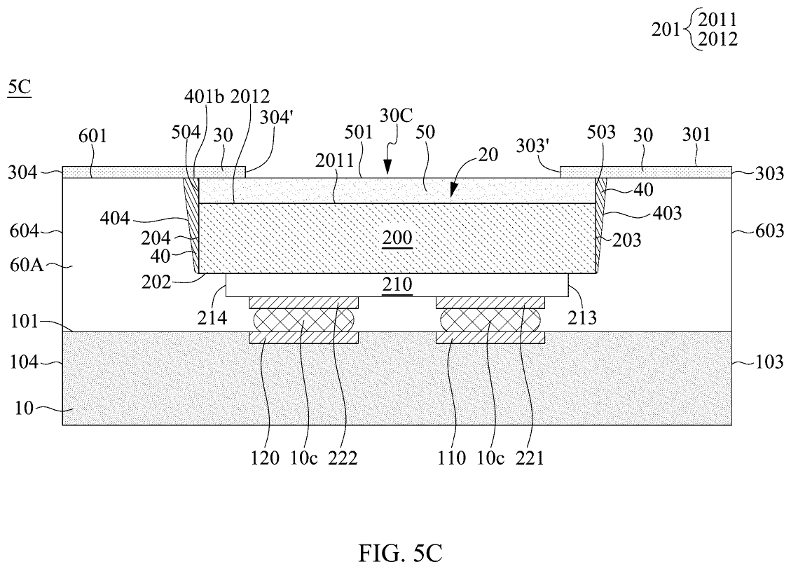

FIG. 5A is a cross-section of a semiconductor package structure 5A in accordance with some arrangements of the present disclosure. The semiconductor package structure 5A is similar to the semiconductor package structure 4A in FIG. 4A, and the differences therebetween are described as follows.

In some arrangements, the reflective element 40 is disposed only within all lateral extents (e.g., the sidewalls) of the optical component 20. In some arrangements, the reflective element 40 contacts the sidewalls 203 and 204 of the optical component 20. In some arrangements, the reflective element 30 extends over a sloping side (e.g., the sidewalls 403 and 404) of the reflective element 40.

In some arrangements, the reflective element 30 includes an air-penetration layer exposing the region 2011 of the surface 201 to air. In some arrangements, the reflective element 40 includes a metal layer, and a thickness uniformity of the reflective element 40 is less than a thickness uniformity of the portion 310 of the reflective element 30.

FIG. 5B is a cross-section of a semiconductor package structure 5B in accordance with some arrangements of the present disclosure. The semiconductor package structure 5B is similar to the semiconductor package structure 4A in FIG. 4A, and the differences therebetween are described as follows.

In some arrangements, the reflective element 30 includes a stepwise sidewall (e.g., the sidewalls 303′ and 304′) over the region 2012 of the surface 201. In some arrangements, the stepwise sidewall defines an air outlet (e.g., the opening 30C) exposing the region 2011 of the surface 201 (or the emitting surface). The stepwise structure of the reflective element 30 with at least two steps may be formed by forming the reflective element 30 conformally over the reflective element 40 and the region 2012 of the surface 201. In some arrangements, a reflective layer may be formed over the reflective element 40 and the surface 201, and an etching operation may be performed on the reflective layer until the region 2011 of the surface 201 is exposed. As a result, a stepwise configuration with at least two steps is formed. In some arrangements, the stepwise structure of the reflective element 30 conforms in shape to the reflective element 40 and the region 2012 of the surface 201, and thus the stepwise configuration can provide a relatively uniform distribution of stress on the underlying layers. Therefore, the stepwise configuration of the reflective element 30 can reduce the stress over the semiconductor package structure.

In some arrangements, the reflective element 40 is connected to the reflective element 30 and encapsulates the optical component 20. In some arrangements, the reflective element 40 (or the portion 420) abuts at least the sidewalls 203 and 204 of the optical component 20. In some arrangements, the reflective element 30 and the reflective element 40 collectively define a common air passage exposing the region 2011 of the surface 201 (or the emitting surface). In some arrangements, the opening 30C and the opening 40C collectively form the common air passage.

FIG. 5C is a cross-section of a semiconductor package structure 5C in accordance with some arrangements of the present disclosure. The semiconductor package structure 5C is similar to the semiconductor package structure 4A in FIG. 4A, and the differences therebetween are described as follows.

In some arrangements, the reflective element 30 includes an anti-warpage bar protruding from the sidewalls 203 and 204 of the optical component 20 in a cross-sectional view perspective. In some arrangements, an upper surface 401b of the reflective element 40 substantially aligns with an upper surface (e.g., the surface 501) of the transparent cover 50.

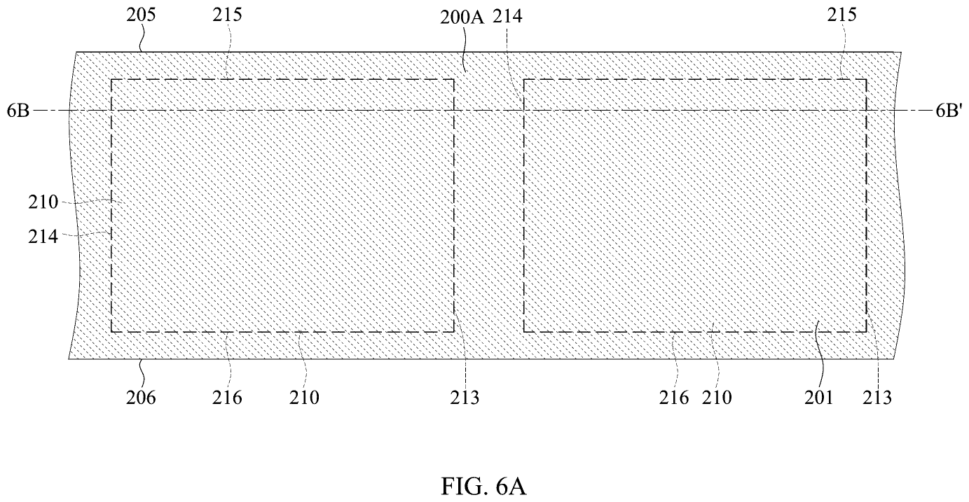

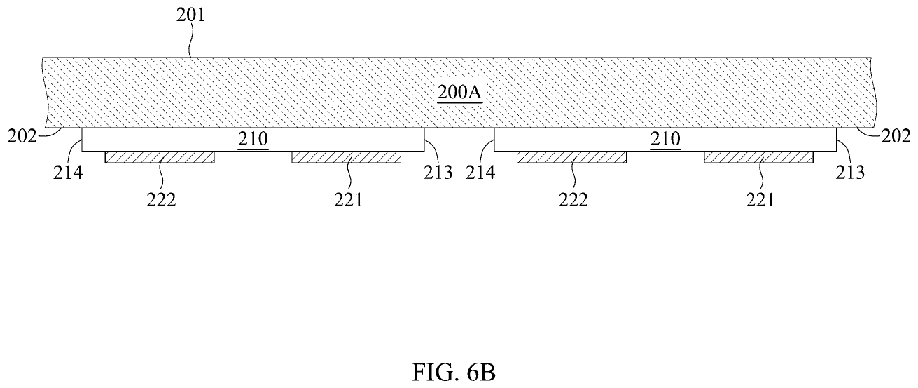

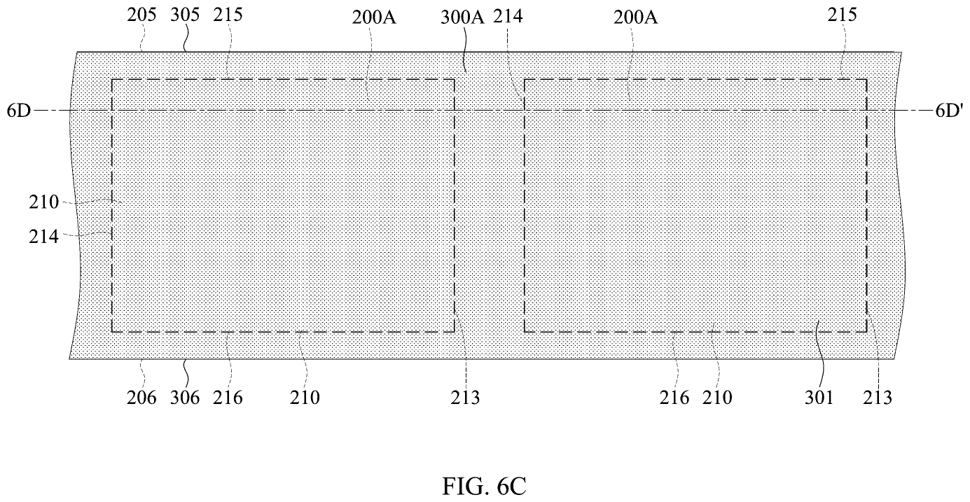

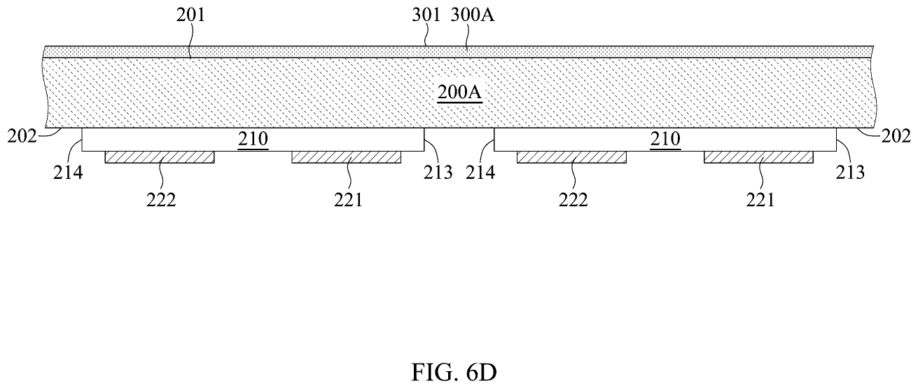

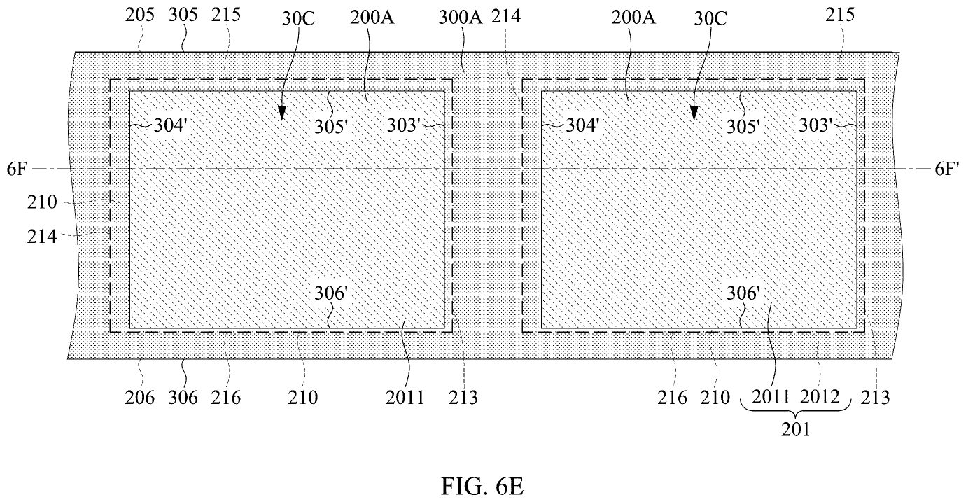

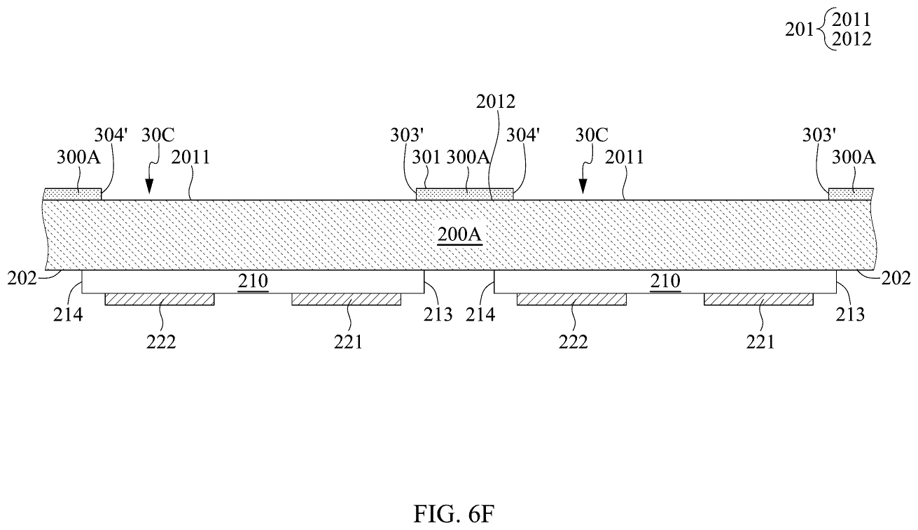

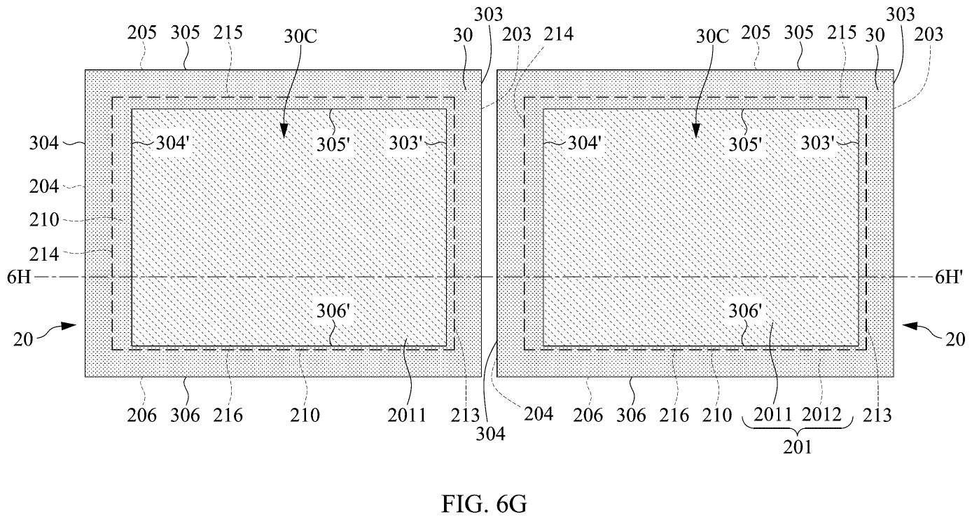

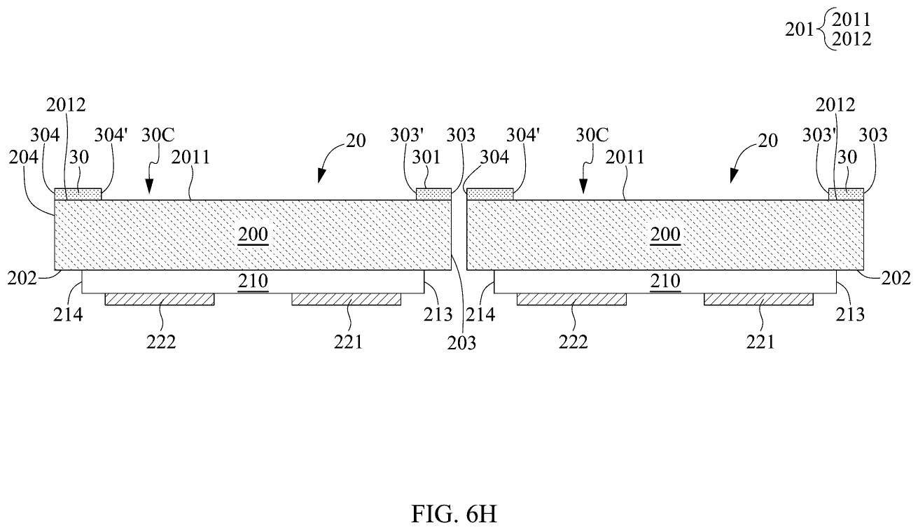

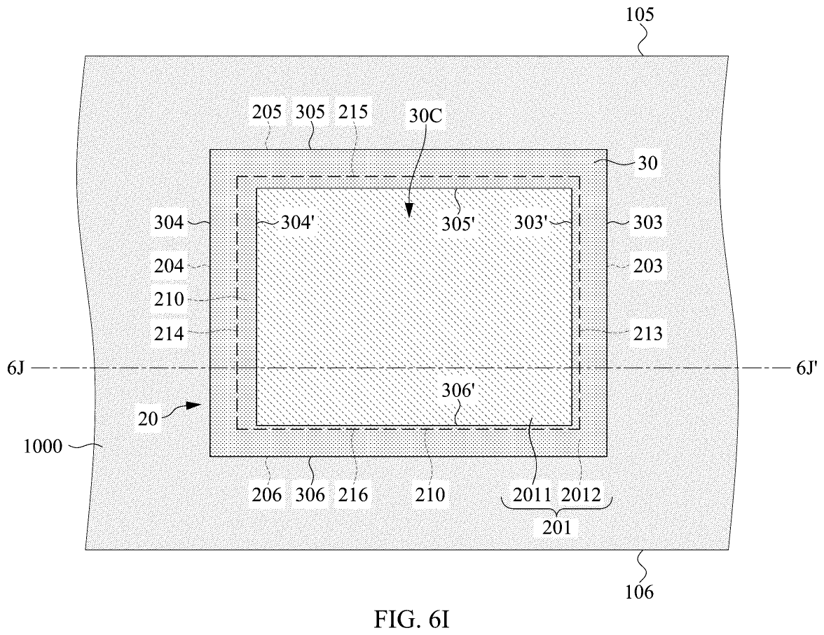

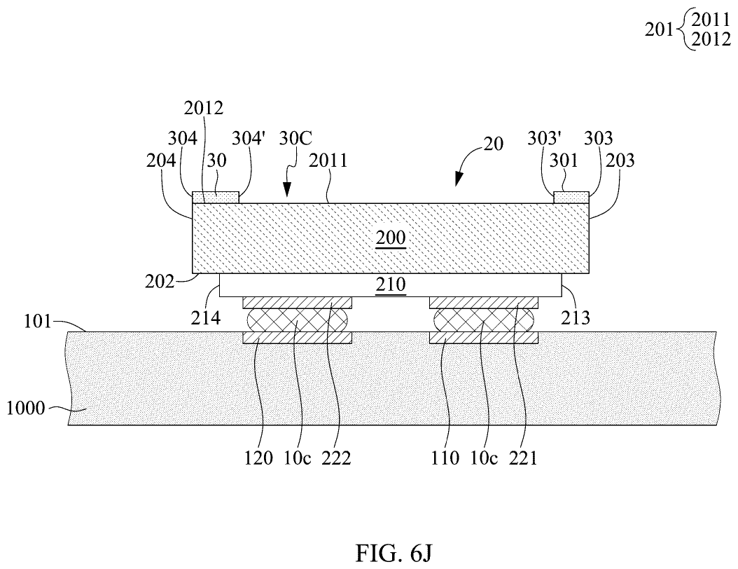

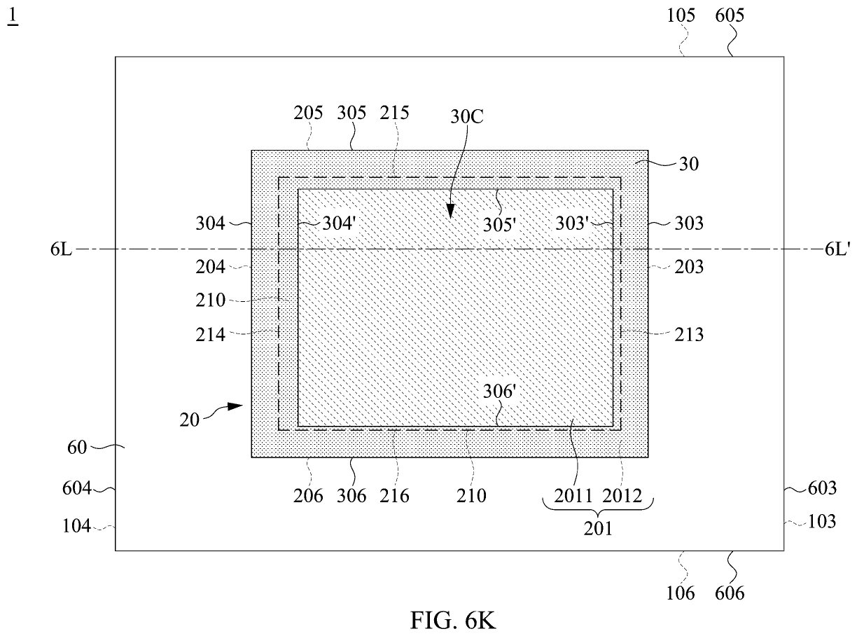

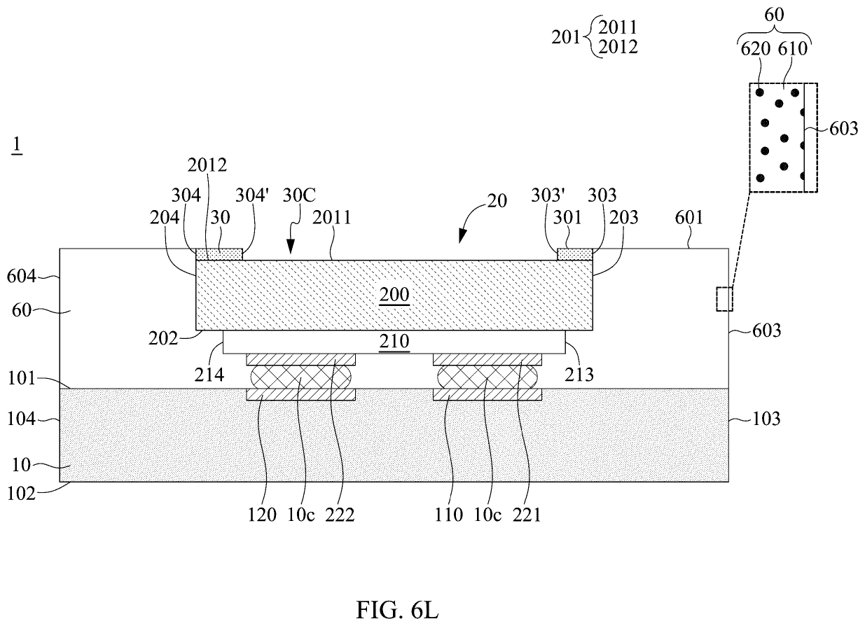

FIG. 6A to FIG. 6L illustrate various stages of an exemplary method for forming a semiconductor package structure 1 in accordance with some arrangements of the present disclosure.

Referring to FIG. 6A and FIG. 6B, FIG. 6B shows a cross-section along a line 6B-6B′ in FIG. 6A. A strip-level (or a panel-level) optical structure may be provided. The strip-level optical structure may include a base layer 200A having surfaces 201 and 202, emitting layers 210 on the surface 202, and electrodes 221 and 222 connected to the emitting layers 210. The base layer 200A may have sidewalls 205 and 206. The emitting layer 210 may have sidewalls 213, 214, 215, and 216.

Referring to FIG. 6C and FIG. 6D, FIG. 6D shows a cross-section along a line 6D-6D′ in FIG. 6C. A reflective layer 300A may be formed on the surface 201 of the base layer 200A. The reflective layer 300A may have sidewalls 305 and 306. The reflective layer 300A may be formed by plating, deposition, coating, or any suitable process.

Referring to FIG. 6E and FIG. 6F, FIG. 6F shows a cross-section along a line 6F-6F′ in FIG. 6E. Portions of the reflective layer 300A may be removed to form openings 30C that expose regions 2011 of the surface 201. In some arrangements, a detector (e.g., an IR device) may be used to observe edges (e.g., the sidewalls 213, 214, 215, and 216) of the emitting layers 210 from above the surface 201. In some arrangements, the emitting layers 210 can be observed by a detector utilizing a light having a wavelength (e.g., ranging from about 900 nm to about 1700 nm) that is configured to pass through the base layer 200 to determine peripheries of the regions 2011 of the surface 201 for forming the openings 30C. In some arrangements, alignment marks may be formed adjacent to the electrodes 221 and 222, and the detector utilizing a light that is configured to pass through the base layer and used to detect or observe the alignment marks to determine the peripheries of the regions 2011 of the surface 201 for forming the openings 30C. Next, in some arrangements, a heating device (e.g., a laser) may be used to remove the portions of the reflective layer 300A that are above the predetermined regions 2011 of the surface 201. In some arrangements, a first portion of the reflective layer 300A may be removed by a first laser shot to form a first opening 30C, a second portion of the reflective layer 300A may be removed by a second laser shot to form a second opening 30C, and additional portions of the reflective layer 300A may be removed by further laser shots to form additional openings 30C after the second laser shot. In some arrangements, after the opening 30C are formed, the reflective layer 300C forms a reflective grid. In some arrangements, each of the openings 30C of the reflective grid may be used to ensure that lights are emitted through the region 2011 of the surface 201 without emitting through the region 2012 of the surface 201 of the optical component 20, such that the loss in light emitting efficiency can be decreased.

Referring to FIG. 6G and FIG. 6H, FIG. 6H shows a cross-section along a line 6H-6H′ in FIG. 6G. A singulation operation may be performed to form a plurality of optical components 20 from the strip-level optical structure. In some arrangements, the singulation operation may be performed by laser cutting, mechanical cutting, or any suitable singulation process. The sidewalls of the optical component 20 may be substantially aligned with the sidewalls of the reflective element 30 due to the singulation operation that form these sidewalls.

Referring to FIG. 6I and FIG. 6J, FIG. 6J shows a cross-section along a line 6J-6J′ in FIG. 6I. A strip-level substrate 1000 including pads 110 and 120 may be provided, and a plurality of optical components 20 may be connected to the strip-level substrate 1000 through electrical contacts 10c.

Referring to FIG. 6K and FIG. 6L, FIG. 6L shows a cross-section along a line 6L-6L′ in FIG. 6K. A reflective layer may be formed to cover or encapsulate the optical components 20, the reflective elements 30, and the electrical contacts 10c on the strip-level substrate 1000, and then a singulation operation may be performed on the reflective layer and the strip-level substrate 1000 to form reflective elements 60 and substrates 10. The sidewalls of the reflective element 60 may be substantially aligned with the sidewalls of the substrate 10 due to the singulation operation that form these sidewalls. As such, the semiconductor package structure 1 illustrated in FIG. 1A may be formed.

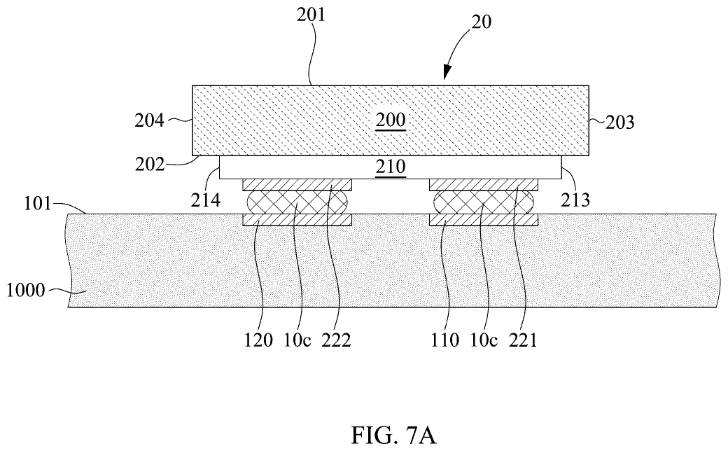

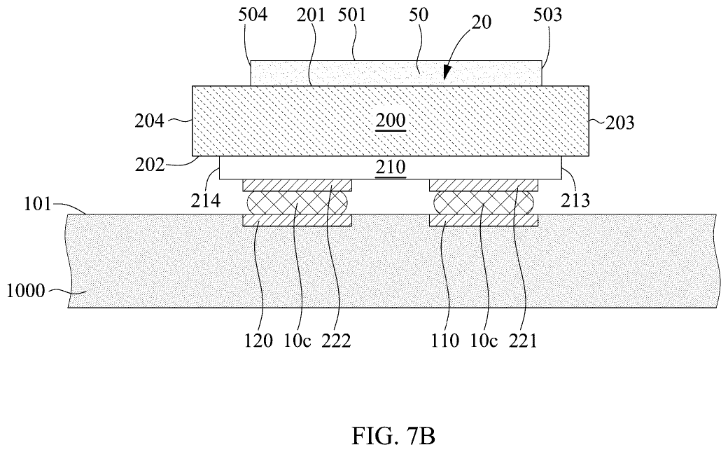

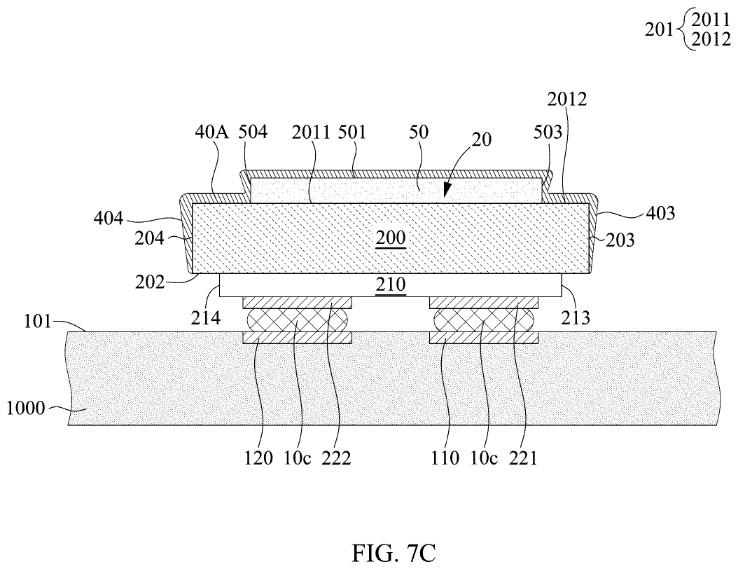

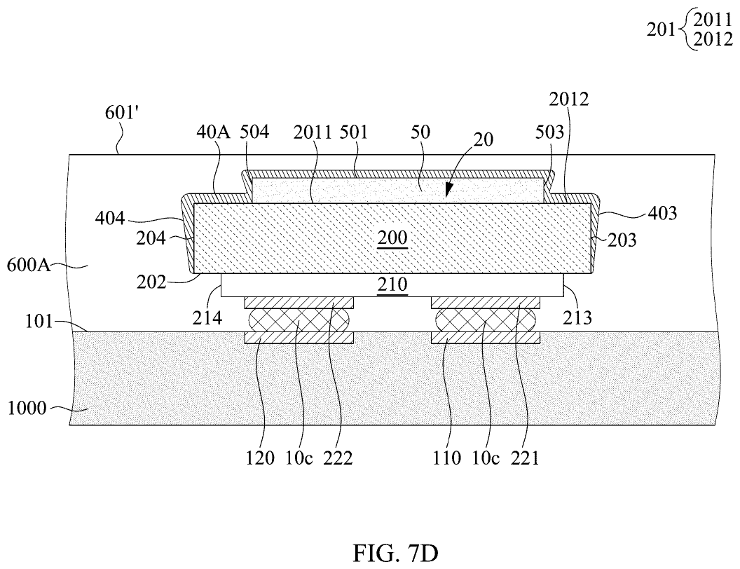

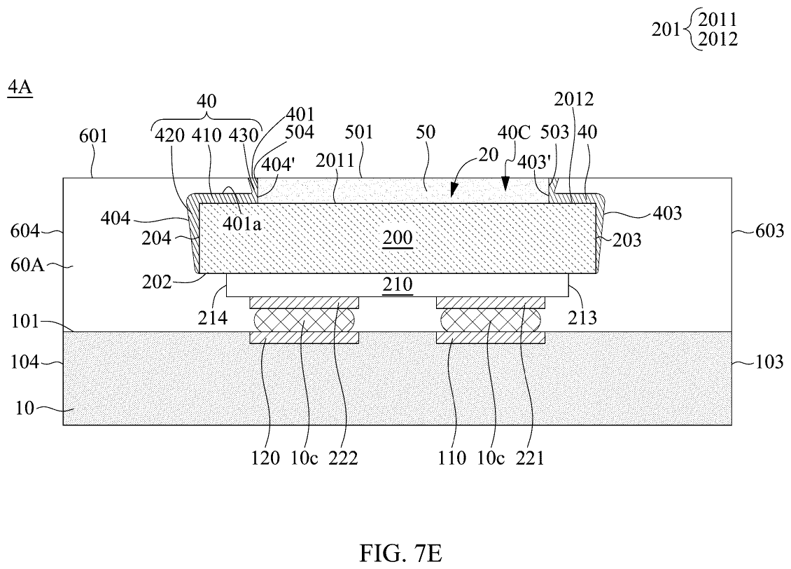

FIG. 7A to FIG. 7E illustrate various stages of an exemplary method for forming a semiconductor package structure 4A in accordance with some arrangements of the present disclosure.

Referring to FIG. 7A, operations similar those illustrated in FIGS. 6A-6J may be performed to connect optical components 20 to a strip-level substrate 1000, except that the reflective elements 30 are not formed on the surfaces 201 of the optical components 20.

Referring to FIG. 7B, a transparent cover 50 may be formed over a region of the surface 201 of the optical component 20. In some arrangements, a plurality of transparent covers 50 may be disposed on and attached to the regions of the surfaces 201 of the optical components 20 over the strip-level substrate 1000. In some arrangements, a mask may be disposed over the optical components 20, the mask may have openings that expose regions of the surfaces 201 of the optical components 20, a transparent material may be applied through the openings of the mask to form a plurality of transparent portions over the regions of the surfaces 201, and then a curing operation may be performed on the transparent portions to form transparent covers 50 on the regions of the surfaces 201 of the optical components 20.

Referring to FIG. 7C, a reflective layer 40A may be formed over the transparent cover 50 and the exposed portions of the surface 201 of the optical component 20. In some arrangements, the reflective layer 40A contacts a region 2012 of the surface 201 with the transparent cover 50 contacting a region 2012 of the surface 201. The reflective layer 40A may be formed by plating, deposition, coating, or any suitable process. In some arrangements, a reflective coating including a gel and metal nanoparticles dispersed in the gel may be coating on the transparent cover 50 and the exposed portions of the surface 201 of the optical component 20, and a thermal treatment may be performed to melt the metal nanoparticles into a metal layer (e.g., the reflective layer 40A). In some arrangements, the thermal treatment is performed under a temperature lower than a reflow temperature (e.g. 260 °C-270 °C) of solder materials.

Referring to FIG. 7D, an encapsulant layer 600A may be formed to encapsulate the optical components 20 and the reflective layers 40A over the strip-level substrate 1000. The encapsulant layer 600A may have an upper surface 601′ above the reflective layers 40A.

Referring to FIG. 7E, the encapsulant layer 600A is partially removed to expose the transparent cover 50 and the reflective element 40 from an upper surface (e.g., the surface 601) of the as-formed cover element 60A. The encapsulant layer 600A may be partially removed by a grinding operation. In some arrangements, a singulation operation on the encapsulant layer 600A and the strip-level substrate 1000 may be performed before or after the grinding operation. As such, the semiconductor package structure 4A illustrated in FIG. 4A may be formed.

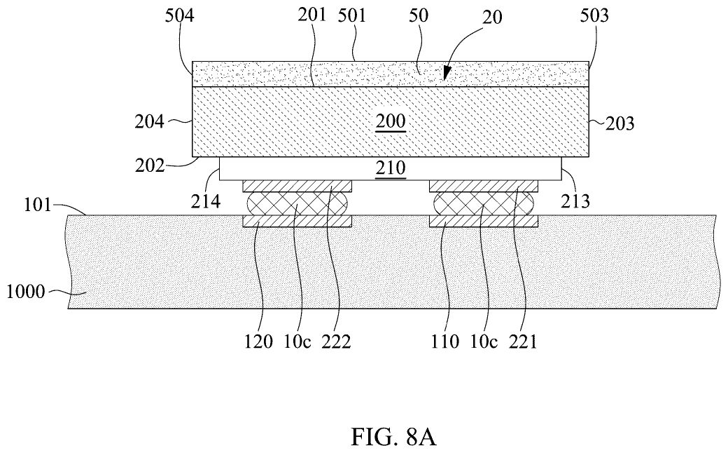

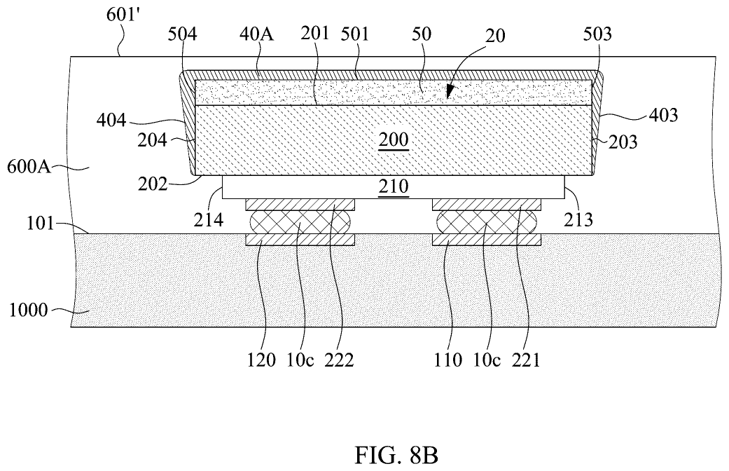

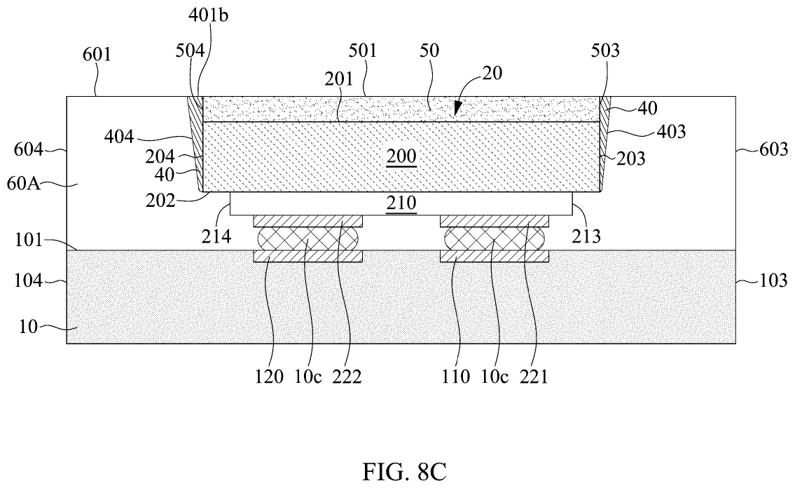

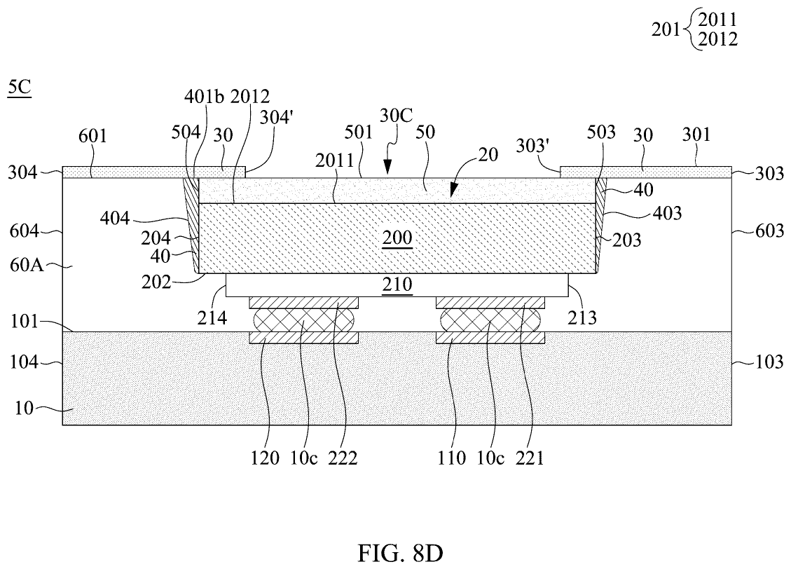

FIG. 8A to FIG. 8D illustrate various stages of an exemplary method for forming a semiconductor package structure 5C in accordance with some arrangements of the present disclosure.

Referring to FIG. 8A, operations similar those illustrated in FIGS. 6A-6J may be performed to connect optical components 20 to a strip-level substrate 1000, and transparent covers 50 may be formed on the surfaces 201 of the optical components 20. In some arrangements, a plurality of transparent covers 50 may be disposed on and attached to the surfaces 201 of the optical components 20 over the strip-level substrate 1000. In some arrangements, a transparent layer may be formed on the surface 201 of the base layer 200A of the strip-level optical structure when performing operations similar to those illustrated in FIGS. 6C-6D, and then a singulation operation is performed on the transparent layer and the base layer 200A when performing operations similar to those illustrated in FIGS. 6G-6H to form the transparent cover 50 having sidewalls that are substantially aligned with the sidewalls of the optical component 20.

Referring to FIG. 8B, operations similar to those illustrated in FIGS. 7C-7D may be performed to form a reflective layer 40A and an encapsulant layer 600A.

Referring to FIG. 8C, operation similar to those illustrated in FIG. 7E may be performed to form the cover element 60A and the reflective element 40 exposed by the cover element 60A.

Referring to FIG. 8D, a reflective element 30 may be formed over the optical component 20, the reflective element 40, and the cover element 60A to expose a region 2011 of the surface 201 of the optical component 20. The reflective element 30 having an opening 30C may be formed by operations similar to those illustrated in FIGS. 6E-6F. The encapsulant layer 600A and the strip-level substrate 1000 may be singulated before or after partially removing the reflective layer 40A to expose the transparent cover 50. The encapsulant layer 600A and the strip-level substrate 1000 may be singulated before or after forming the reflective element 30. As such, the semiconductor package structure 5C illustrated in FIG. 5C may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor package structure, comprising:
an optical component having an emitting surface;
a first reflective element encapsulating the optical component; and
a second reflective element over the emitting surface and contacting the first reflective element, wherein a first portion of the emitting surface is exposed by the second reflective element.

2. The semiconductor package structure as claimed in claim 1, wherein the first reflective element comprises a diffusor material.

3. The semiconductor package structure as claimed in claim 1, further comprising a baffle structure contacting the first reflective element, wherein an elevation of an upper surface of the first reflective element is lower than an elevation of an upper surface of the baffle structure with respect to the emitting surface.

4. The semiconductor package structure as claimed in claim 1, wherein the second reflective element comprises an anti-warpage bar protruding from a sidewall of the optical component in a cross-sectional view perspective.

5. The semiconductor package structure as claimed in claim 1, wherein the second reflective element defines a transparent window overlapped by the first portion of the emitting surface.

6. The semiconductor package structure as claimed in claim 5, further comprising a polymer lens layer overlapped by the transparent window.

7. The semiconductor package structure as claimed in claim 1, further comprising a cover element encapsulating the first reflective element.

8. A semiconductor package structure, comprising:
an optical component having an emitting surface comprising a first region and a second region, wherein a light emitting uniformity of the second region is lower than a light emitting uniformity of the first region; and
a first reflective element covering the second region of the emitting surface and exposing the first region of the emitting surface.

9. The semiconductor package structure as claimed in claim 8, wherein the first reflective element comprises an air-penetration layer exposing the first region of the emitting surface to air.

10. The semiconductor package structure as claimed in claim 8, further comprising a second reflective element connected to the first reflective element and encapsulating the optical component, wherein the second reflective element comprises a thermal conductive film extending over sidewalls of the optical component.

11. The semiconductor package structure as claimed in claim 10, further comprising a thermal insulation layer contacting the first reflective element and the second reflective element.

12. The semiconductor package structure as claimed in claim 8, further comprising a transparent cover over the first region of the emitting surface, wherein the transparent cover comprises an embedded buffer connecting the first reflective element to the emitting surface.

13. The semiconductor package structure as claimed in claim 8, wherein the first reflective element comprises a stepwise sidewall over the second region of the emitting surface and defining an air outlet exposing the first region of the emitting surface.

14. A semiconductor package structure, comprising:
an optical component having an emitting surface configured to emit a light of a varying intensity; and
a reflective element covering an edge region of the emitting surface and exposing a central region of the emitting surface.

15. The semiconductor package structure as claimed in claim 14, further comprising a reflective wall covering sidewalls of the optical component.

16. The semiconductor package structure as claimed in claim 15, further comprising a substrate and electrical contacts connecting the optical component to the substrate, wherein the reflective wall covers the electrical contacts.

17. The semiconductor package structure as claimed in claim 15, wherein the reflective wall comprises a metal layer, and a thickness uniformity of the reflective wall is less than a thickness uniformity of the reflective element.

18. The semiconductor package structure as claimed in claim 17, further comprising an encapsulant encapsulating the reflective element and the reflective wall and free from contacting the emitting surface, wherein the reflective wall tapers in a direction away from the reflective element.

19. The semiconductor package structure as claimed in claim 14, further comprising a polymer lens layer covering the central region of the emitting surface and contacting the reflective element.

20. The semiconductor package structure as claimed in claim 14, wherein the optical component comprises an emitting layer vertically overlapped with the central region of the emitting surface, and a center of the emitting layer is misaligned with a center of the central region of the emitting surface.
